(19) United States
(12) Patent Application Publication
(10) Pub. No.: US 2024/0130126 A1
(43) Pub. Date: Apr. 18, 2024

(54) NON-VOLATILE MEMORY DEVICE, METHOD FOR MANUFACTURING THE NON-VOLATILE MEMORY DEVICE, AND ELECTRONIC SYSTEM INCLUDING THE NON-VOLATILE MEMORY DEVICE

(71) Applicant: Samsung Electronics Co., Ltd., Suwon-si (KR)

(72) Inventors: Yeong Dong MUN, Suwon-si (KR); Seong Hun PARK, Suwon-si (KR); Hauk HAN, Suwon-si (KR); Seong Jin KIM, Suwon-si (KR)

(73) Assignee: Samsung Electronics Co., Ltd., Suwon-si (KR)

(21) Appl. No.: 18/349,460

(22) Filed: Jul. 10, 2023

(30) Foreign Application Priority Data
Oct. 13, 2022 (KR) 10-2022-0131065

(51) Int. Cl. H10B 43/27; H10B 43/35

(52) U.S. Cl. CPC H10B 43/27; H10B 43/35

(57) ABSTRACT

A non-volatile memory device including a substrate including a first area and a second area, a mold structure on the substrate, the mold structure including gate electrodes and mold insulating films alternately stacked on each other in a stepwise manner, an interlayer insulating film covering the mold structure, a channel structure on the first area, the channel structure extending through the mold structure and connected to the gate electrodes, and a through-contact on the second area and extending through the interlayer insulating film, the through-contact including a first portion in a first trench and a second portion in a second trench, the first portion including a liner film along a sidewall and a bottom surface of the first trench and a filling film on the liner film, wherein the filling film being a multi-grain conductive material, and the second portion being a single grain conductive material, may be provided.

### CROSS-REFERENCE TO RELATED APPLICATION

This application claims priority from Korean Patent Application No. 10-2022-0131065 filed on Oct. 13, 2022 in the Korean Intellectual Property Office, and all the benefits accruing therefrom under 35 U.S.C. 119, the contents of which in its entirety are herein incorporated by reference.

### BACKGROUND

### Field

The present disclosure relates to non-volatile memory devices, methods for manufacturing the non-volatile memory device, and/or electronic systems including the non-volatile memory device.

### Description of Related Art

In order to meet high performance and low price of a non-volatile memory device as demanded by consumers, it is required to increase integration of the non-volatile memory device. The integration of the non-volatile memory devices is an important factor in determining a price thereof. Thus, the non-volatile memory device having increased integration is particularly required.

Integration of a two-dimensional (2D) or planar non-volatile memory device is largely determined based on an occupancy area of a unit memory cell, and therefore is greatly affected by a level of a fine pattern formation skill. However, ultra-expensive equipment is required for formation of fine patterns. Thus, although the integration of the 2D non-volatile memory device is increasing, the increase is limited. Accordingly, a three-dimensional non-volatile memory device including three-dimensionally arranged memory cells has been proposed.

### SUMMARY

An objective to be achieved by the present disclosure is to provide non-volatile memory devices with improved reliability.

Another objective to be achieved by the present disclosure is to provide methods for manufacturing a non-volatile memory device with improved reliability.

Still another objective to be achieved by the present disclosure is to provide electronic systems including a non-volatile memory device with improved reliability.

Objectives and advantages according to the present disclosure are not limited to the above-mentioned objectives and advantages. Other purposes and advantages according to the present disclosure that are not mentioned may be understood based on following descriptions, and may be more clearly understood based on some example embodiments according to the present disclosure. Further, it will be easily understood that the purposes and advantages according to the present disclosure may be realized using means illustrated in the claims and combinations thereof.

According to an aspect of the present disclosure, a non-volatile memory device includes a substrate including a first area and a second area, a mold structure on the substrate, the mold structure including a plurality of gate electrodes and a plurality of mold insulating films that are alternately stacked on top of each other and stacked in a stepwise manner, an interlayer insulating film covering the mold structure, a channel structure on the first area of the substrate, the channel structure extending through the mold structure and connected to the plurality of gate electrode, and a through-contact disposed on the second area of the substrate and extending through the interlayer insulating film, wherein the through-contact includes a first portion in a first trench and a second portion in a second trench, the second trench is on the first trench, the first portion includes a liner film along a sidewall and a bottom surface of the first trench and a filling film on the liner film, the filling film is a multi-grain conductive material, wherein the second portion is a single grain conductive material.

According to another aspect of the present disclosure, a non-volatile memory device includes a substrate including a first area and a second area, a mold structure on the substrate, the mold structure including a plurality of gate electrodes and a plurality of mold insulating films that are alternately stacked on top of each other and stacked in a stepwise manner, an interlayer insulating film covering the mold structure, a channel structure on the first area of the substrate, the channel structure extending through the mold structure and connected to the plurality of gate electrode, and a through-contact on the second area of the substrate and extending through the interlayer insulating film, wherein the through-contact includes a first portion in a first trench and being multiple layers, and a second portion in a second trench and being a single layer, the second trench is on the first trench, the first portion includes a liner film along a sidewall and a bottom surface of the first trench and a filling film on the liner film, the filling film includes a first portion on one sidewall of the first trench and a second portion on an opposite sidewall of the first trench, and a boundary line is at a boundary between the first area and the second area.

According to another aspect of the present disclosure, a method for manufacturing a non-volatile memory device includes providing a substrate including a first area and a second area, forming a mold structure on the substrate, the mold structure including a plurality of gate electrodes and a plurality of mold insulating films that are stacked in a stepwise manner and are alternately stacked on top of each other, forming an interlayer insulating film to cover the mold structure, forming a channel structure on the first area of the substrate to extend through the mold structure and to be connected to the plurality of gate electrodes, forming a trench on the second area of the substate to extend through the interlayer insulating film, the trench including a first trench and a second trench disposed on the first trench, forming a pre-liner film along a sidewall and a bottom surface of the trench, forming an inhibiting layer on a portion of the pre-liner film, which is disposed on a sidewall of the second trench, such that the inhibiting layer is not formed on a portion of the pre-liner film disposed on a sidewall of the first trench, and forming a through-contact in the trench, wherein the through-contact includes a first portion disposed in the first trench and a second portion disposed in the second trench, the first portion includes a liner film disposed along the sidewall and a bottom surface of the first trench and a filling film disposed on the liner film, the filling film is made of a multi-grain conductive material, and the second portion is made of a single grain conductive material.

According to another aspect of the present disclosure, an electronic system includes a main substrate, a non-volatile memory device disposed on the main substrate, and a controller disposed on the main substrate, and electrically connected to the non-volatile memory device, wherein the non-volatile memory device includes a substrate including a first area and a second area, a mold structure on the substrate, the mold structure including a plurality of gate electrodes and a plurality of mold insulating films that are alternately stacked on top of each other and stacked in a stepwise manner, an interlayer insulating film covering the mold structure, a channel structure on the first area of the substrate, the channel structure extending through the mold structure and connected to the plurality of gate electrode, and a through-contact on the second area of the substrate and extending through the interlayer insulating film, the through-contact includes a first portion in a first trench and a second portion in a second trench, the second trench being on the first trench, the first portion includes a liner film along a sidewall and a bottom surface of the first trench and a filling film on the liner film, the filling film is a multi-grain conductive material, and the second portion is a single grain conductive material.

### BRIEF DESCRIPTION OF DRAWINGS

The above and other aspects and features of the present disclosure will become more apparent by describing in detail embodiments thereof with reference to the attached drawings, in which:

FIG. 1 is an illustrative block diagram for illustrating a non-volatile memory device according to an example embodiment.

FIG. 2 is an illustrative circuit diagram for illustrating a non-volatile memory device according to an example embodiment.

FIG. 3 is an illustrative layout diagram for illustrating a non-volatile memory device according to an example embodiment.

FIG. 4 is a cross-sectional view taken along a line A-A of FIG. 3.

FIG. 5 is an enlarged view of a P area of FIG. 4.

FIG. 6 is a cross-sectional view taken along a line B-B in FIG. 3.

FIG. 7 is an enlarged view of a Q area of FIG. 6.

FIG. 8 to FIG. 11 are illustrative views of a through-contact according to some example embodiments.

FIG. 12 is an illustrative diagram of a non-volatile memory device in accordance with an example embodiment.

FIG. 13 is an illustrative diagram of a non-volatile memory device in accordance with an example embodiment.

FIG. 14 is an enlarged view of a R area of FIG. 13.

FIG. 15 and FIG. 16 are illustrative views of a through-contact in accordance with some example embodiments.

FIG. 17 is an illustrative diagram of a non-volatile memory device in accordance with an example embodiment.

FIG. 18 is an enlarged view of a S area of FIG. 17.

FIG. 19 to FIG. 33 are diagrams for illustrating a method for manufacturing a non-volatile memory device according to an example embodiment.

FIG. 34 is an illustrative block diagram for illustrating an electronic system according to an example embodiment.

FIG. 35 is an illustrative perspective view for illustrating an electronic system according to an example embodiment.

FIG. 36 is a schematic cross-sectional view taken along a line I-I of FIG. 35.

### DETAILED DESCRIPTIONS

Although the first, second, etc. are used to describe various elements and/or components, these elements and/or components are of course not limited by these terms. These terms are only used to distinguish one element or component from another element or component. Therefore, the first device or the first component mentioned below may be a second device or a second component within the technical spirit of the present disclosure.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

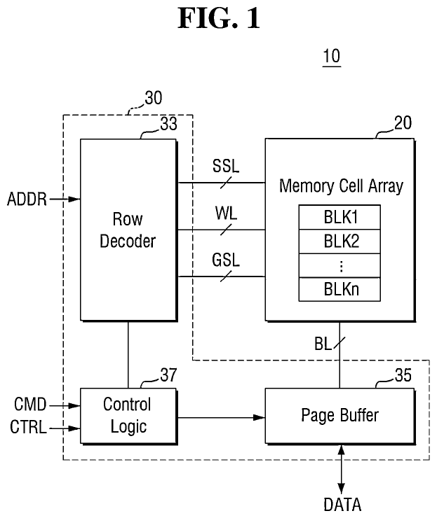

Hereinafter, some example embodiments of the present disclosure will be described in detail with reference to the accompanying drawings. The same reference numerals are used for the same components in the drawings, and duplicate descriptions thereof are omitted. Hereinafter, a non-volatile memory device according to illustrative embodiments will be described with reference to FIG. 1 to FIG. 7.

FIG. 1 is an illustrative block diagram for illustrating a non-volatile memory device according to an example embodiment.

Referring to FIG. 1, a non-volatile memory device 10 according to an example embodiment includes a memory cell array 20 and a peripheral circuit 30.

The memory cell array 20 may include a plurality of memory cell blocks (BLK1 to BLKn). Each of the memory cell blocks BLK1 to BLKn may include a plurality of memory cells. The memory cell array 20 may be connected to the peripheral circuit 30 via a bit-line BL, a word-line WL, at least one string select line SSL, and at least one ground select line GSL. For example, the memory cell blocks BLK1 to BLKn may be connected to a row decoder 33 via the word-line WL, the string select line SSL, and the ground select line GSL. Further, the memory cell blocks BLK1 to BLKn may be connected to a page buffer 35 via the bit-line BL.

The peripheral circuit 30 may receive an address ADDR, a command CMD, and a control signal CTRL from an external device to the non-volatile memory device 10, and may transmit and receive data DATA to and from an external device to the non-volatile memory device 10. The peripheral circuit 30 may include a control logic 37, the row decoder 33, and the page buffer 35. Although not shown, the peripheral circuit 30 may further include various sub-circuits such as an input/output circuit, a voltage generation circuit for generating various voltages desired for an operation of the non-volatile memory device 10, and an error correction circuit for correcting an error of the data DATA read from the memory cell array 20.

The control logic 37 may be connected to the row decoder 33, the input/output circuit, and the voltage generation circuit. The control logic 37 may control overall operations of the non-volatile memory device 10. The control logic 37 may generate various internal control signals used in the non-volatile memory device 10 in response to the control signal CTRL. For example, the control logic 37 may adjust a voltage level of a voltage supplied to the word-line WL and the bit-line BL when performing a memory operation such as a program operation or an erase operation.

The row decoder 33 may select at least one of the plurality of memory cell blocks BLK1 to BLKn in response to the address ADDR, and may select at least one word-line WL, at least one string select line SSL, and at least one ground select line GSL of the selected at least one memory cell block BLK1 to BLKn. Further, the row decoder 33 may transmit a voltage for performing a memory operation to the word-line WL of the selected at least one memory cell block BLK1 to BLKn.

The page buffer 35 may be connected to the memory cell array 20 via the bit-line BL. The page buffer 35 may operate as a writer driver or a sense amplifier. For example, when performing a program operation, the page buffer 35 operates as the writer driver to apply a voltage based on the data DATA to be stored in the memory cell array 20 to the bit-line BL. On the other hand, when performing a read operation, the page buffer 35 may operate as the sense amplifier to detect the data DATA stored in the memory cell array 20.

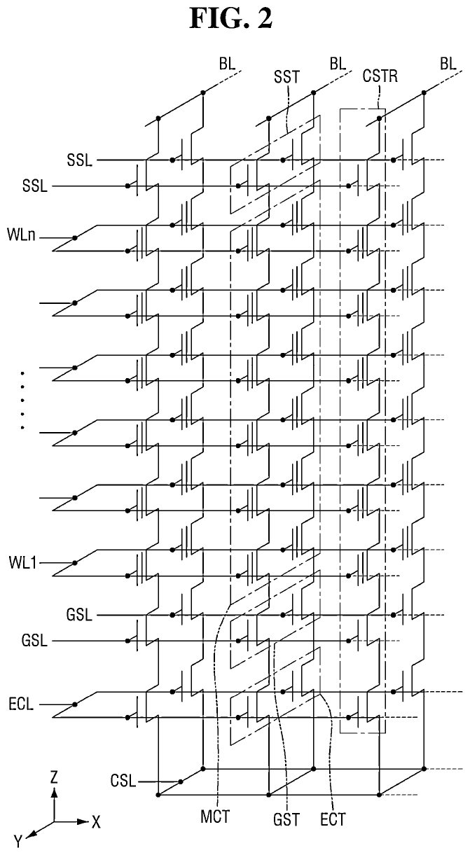

FIG. 2 is an illustrative circuit diagram for illustrating a non-volatile memory device according to an example embodiment.

Referring to FIG. 2, a memory cell array (e.g., 20 in FIG. 1) of a non-volatile memory device according to an example embodiment includes a common source line CSL, a plurality of bit-lines BL, and a plurality of cell strings CSTR.

The common source line CSL may extend in the first direction X. In some embodiments, a plurality of common source lines CSL may be arranged in a two-dimensional manner. For example, the plurality of common source lines CSL may be spaced apart from each other and extend in the first direction X. The same voltage may be applied to the common source lines CSL. In some example embodiments, different voltages may be individually applied to be the common source lines CSL.

The plurality of bit-lines BL may be arranged in a two-dimensional manner. For example, the bit-lines BL may be spaced apart from each other and extend in the second direction Y intersecting the first direction X. The plurality of cell strings CSTR may be connected in parallel to each of the bit-lines BL. The cell strings CSTR may be connected to the common source line CSL. That is, the plurality of cell strings CSTR may be disposed between the bit-lines BL and the common source line CSL.

Each of the cell strings CSTR may include a ground select transistor GST connected to the common source line CSL, a string select transistor SST connected to the bit-line BL, and a plurality of memory cell transistors MCT disposed between the ground select transistor GST and the string select transistor SST. Each of the memory cell transistors MCT may include a data storage element. The ground select transistor GST, the string select transistor SST and the memory cell transistors MCT may be connected in series to each other.

The common source line CSL may be commonly connected to sources of the ground select transistors GST. Further, a ground select line GSL, a plurality of word-lines WL1 to WLn and a string select line SSL may be disposed between the common source line CSL and the bit-line BL. The ground select line GSL may act as a gate electrode of the ground select transistor GST. The word-lines WL1 to WLn may be used as gate electrodes of the memory cell transistors MCT, respectively. The string select line SSL may act as a gate electrode of the string select transistor SST.

In some example embodiments, an erase control transistor ECT may be disposed between the common source line CSL and the ground select transistor GST. The common source line CSL may be commonly connected to sources of the erase control transistors ECT. Further, an erase control line ECL may be disposed between the common source line CSL and the ground select line GSL. The erase control line ECL may act as a gate electrode of the erase control transistor ECT. The erase control transistors ECT may generate gate induced drain leakage (GIDL) to execute an erase operation of the memory cell array.

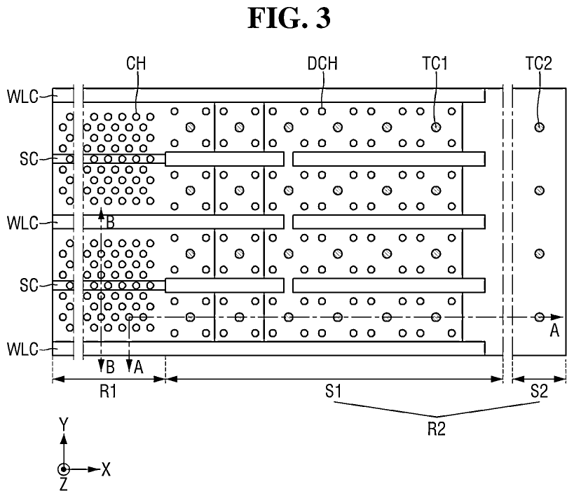

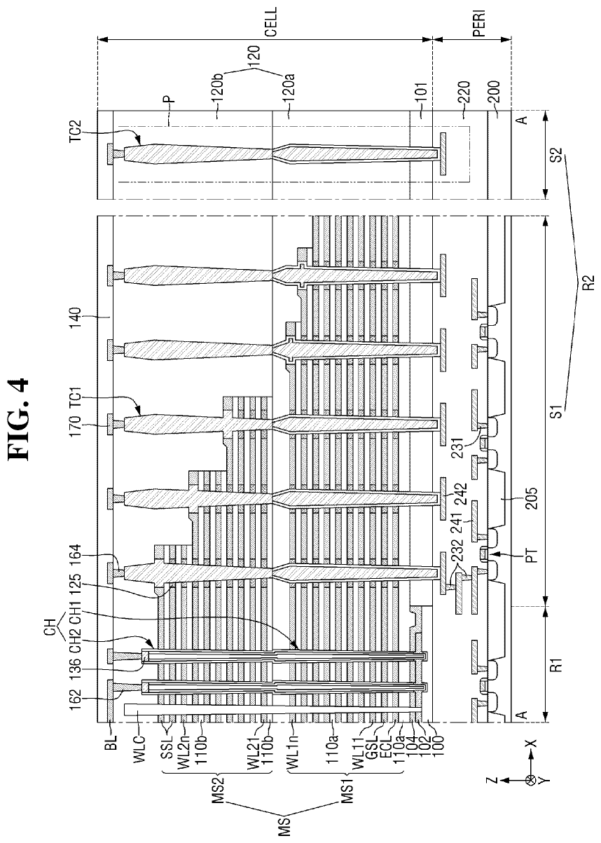

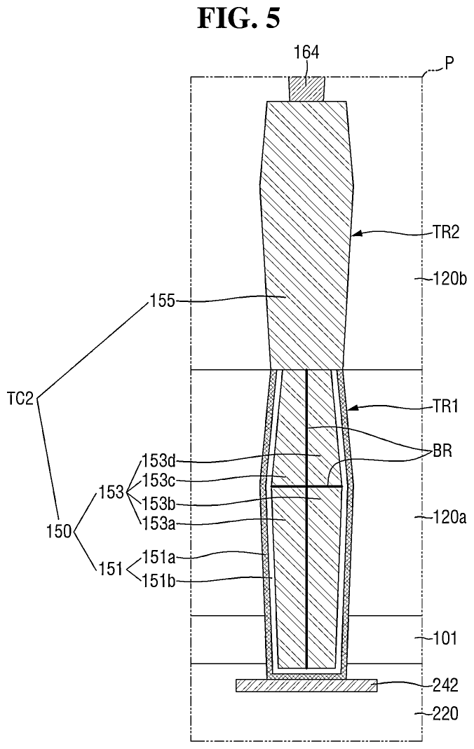

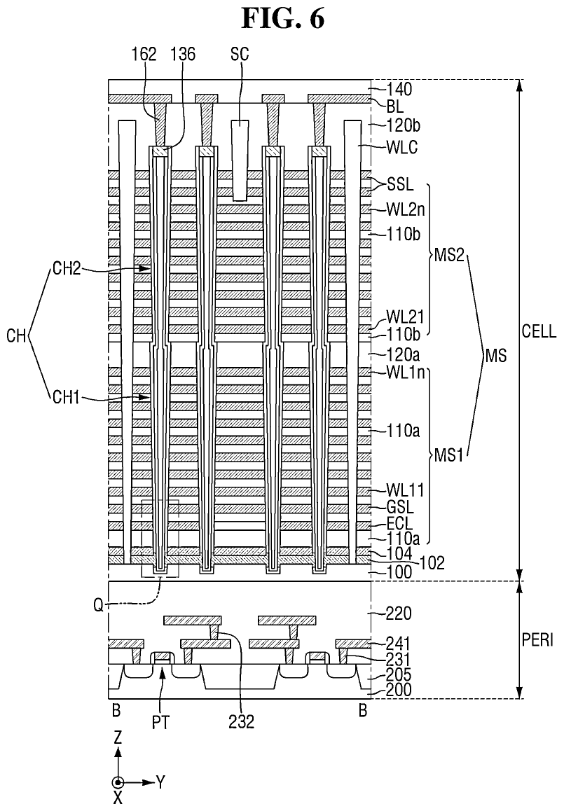

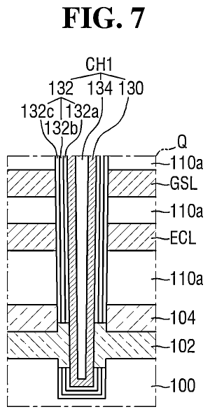

FIG. 3 is an illustrative layout diagram for illustrating a non-volatile memory device according to an example embodiment. FIG. 4 is a cross-sectional view taken along a line A-A of FIG. 3. FIG. 5 is an enlarged view of a P area of FIG. 4. FIG. 6 is a cross-sectional view taken along a line B-B in FIG. 3. FIG. 7 is an enlarged view of a Q area of FIG. 6. For reference, FIG. 5 may be an illustrative conceptual diagram for illustrating a through-contact.

Referring to FIG. 3 to FIG. 7, the non-volatile memory device according to an example embodiment includes a cell structure CELL and a peripheral circuit structure PERI.

The cell structure CELL may include a cell substrate 100, an insulating substrate 101, a mold structure MS, an interlayer insulating film 120, a channel structure CH, a block isolation area WLC, a bit-line BL, through-contacts TC1 and TC2, an insulating ring 125, and a first inter-wiring insulating film 140.

A substrate may include a first area R1 and a second area R2. The second area R2 may include a first sub-area S1 and a second sub-area S2. In some example embodiments, the first area R1 may be a cell array area, the first sub-area S1 may be an extended area, and the second sub-area S2 may be a through area. However, the present disclosure is not limited thereto. The substrate may include, but is not limited to, the cell substrate 100 and the insulating substrate 101.

The cell substrate 100 may include, for example, a semiconductor substrate such as a silicon substrate, a germanium substrate, or a silicon-germanium substrate. Alternatively, the cell substrate 100 may include a silicon-on-insulator (SOI) substrate or a germanium-on-insulator (GOI) substrate. In some example embodiments, the cell substrate 100 may contain therein impurities. For example, the cell substrate 100 may contain therein n-type impurities such as phosphorus (P), arsenic (As), and the like.

A memory cell array (for example, 20 in FIG. 1) including a plurality of memory cells may be disposed in the first area R1. For example, in the first area R1, the channel structure CH, the bit-line BL and first and second gate electrodes ECL, GSL, WL11 to WL1n, WL21 to WL2n, and SSL, etc., which will be described later, may be disposed in the first area R1. In following descriptions, a surface of the cell substrate 100 on which the memory cell array is disposed may be referred to as a front surface (front side) of the cell substrate 100. Conversely, a surface of the cell substrate 100 opposite to the front surface of the cell substrate 100 may be referred to as a rear surface (back side) of the cell substrate 100.

The first sub-area S1 may be disposed around the first area R1. In the first sub-area S1, the first and second gate electrodes ECL, GSL, WL11 to WL1n, WL21 to WL2n, and SSL, which will be described later, may be stacked in a stepwise manner. In the first sub-area S1, first and second mold insulating films 110a and 110b, which will be described later, may be stacked in a stepwise manner.

The insulating substrate 101 may be disposed in the second area R2. The insulating substrate 101 may include, for example, at least one of silicon oxide, silicon nitride, silicon oxynitride, and silicon carbide. However, the present disclosure is not limited thereto. Unlike what is illustrated, the insulating substrate 101 may be disposed in the cell substrate 100.

It is illustrated that a bottom surface of the insulating substrate 101 is coplanar with a bottom surface of the cell substrate 100. However, this is only an example. In another example, a vertical level of the bottom surface of the insulating substrate 101 may be lower than that of the bottom surface of the cell substrate 100.

The mold structure MS may be disposed on the front surface of the cell substrate 100, for example, on a top surface thereof. The mold structure MS may include a first structure MS1 and a second structure MS2. That is, the non-volatile memory device according to some example embodiments may be a 2-stack non-volatile memory device. The second structure MS2 may be disposed on the first structure MS1.

The first structure MS1 may include a plurality of first gate electrodes ECL, GSL, and WL11 to WL1n and a plurality of first mold insulating films 110a that are alternately stacked on top of each other while being disposed on the cell substrate 100. Each of the plurality of first gate electrodes ECL, GSL, and WL11 to WL1n and the plurality of first mold insulating films 110a may have a layer-like structure extending in a parallel manner to the top surface of the cell substrate 100. The plurality of first gate electrodes ECL, GSL, and WL11 to WL1n may be stacked in a stepwise manner in the first sub-area S1. For example, the plurality of first gate electrodes ECL, GSL, and WL11 to WL1n may extend so as to have different lengths in the first direction X and thus may be stacked in a stepwise manner. In some example embodiments, the plurality of first gate electrodes ECL, GSL, and WL11 to WL1n may extend so as to have different lengths in the second direction Y and thus may be stacked in a stepwise manner. Accordingly, each of the first gate electrodes ECL, GSL, and WL11 to WL1n may include a pad area (not shown) not covered with other gate electrodes. The pad area may mean an area in which a first through-contact TC1, which will be described later, and the gate electrodes contact each other.

The second structure MS2 may include a plurality of second gate electrodes WL21 to WL2n, and SSL and a plurality of second mold insulating films 110b alternately stacked on top of each other while being disposed on the first structure MS1. Each of the plurality of second gate electrodes WL21 to WL2n, the SSL and the plurality of second mold insulating films 110b may have a layer-like structure extending in a parallel manner to the top surface of the cell substrate 100. The plurality of second gate electrodes WL21 to WL2n and SSL may be stacked in a stepwise manner in the first sub-area S1. For example, the plurality of second gate electrodes WL21 to WL2n and SSL may extend so as to different lengths in the first direction X and thus may be stacked in a stepwise manner. In some example embodiments, the plurality of second gate electrodes WL21 to WL2n and SSL may extend so as to different lengths in the second direction Y and thus may be stacked in a stepwise manner. Accordingly, each of the second gate electrodes WL21 to WL2n and SSL may include a pad area (not shown) not covered with other gate electrodes. The pad area may mean an area in which the first through-contact TC1 and the gate electrodes contact each other.

In some example embodiments, the first gate electrodes ECL, GSL, WL11 to WL1n may include an erase control line ECL, a ground select line GSL and a plurality of first word-lines WL11 to WL1n that are sequentially stacked on the cell substrate 100. In some other example embodiments, the erase control line ECL may be omitted.

In some example embodiments, the second gate electrodes WL21 to WL2n and SSL may include a plurality of second word-lines WL21 to WL2n and a string select line SSL sequentially stacked on the cell substrate 100. In some other example embodiments, the string select line SSL may be a single line.

Each of the first gate electrodes ECL, GSL, and WL11 to WL1n and the second gate electrodes WL21 to WL2n, and SSL may include a conductive material, for example, a metal such as tungsten (W), cobalt (Co), nickel (Ni), or a semiconductor material such as silicon. However, the present disclosure is not limited thereto. In one example, each of the first gate electrodes ECL, GSL, and WL11 to WL1n and the second gate electrodes WL21 to WL2n, and SSL may include tungsten (W). In some example embodiments, each of the first gate electrodes ECL, GSL, and WL11 to WL1n, and the second gate electrodes WL21 to WL2n, and SSL may have a multilayer structure. For example, when each of the first gate electrodes ECL, GSL, and WL11 to WL1n and the second gate electrodes WL21 to WL2n, and SSL has the multi-layer structure, each of the first gate electrodes ECL, GSL, and WL11 to WL1n and the second gate electrodes WL21 to WL2n, and SSL may include a gate electrode barrier film and a gate electrode filling film. The gate electrode barrier film may include, for example, titanium nitride (TiN), and the gate electrode filling film may include tungsten (W). However, the present disclosure is not limited thereto.

Each of the first mold insulating film 110a and the second mold insulating film 110b may include an insulating material, for example, at least one of silicon oxide, silicon nitride, or silicon oxynitride. However, the present disclosure is not limited thereto. For example, each of the first mold insulating film 110a and the second mold insulating film 110b may include silicon oxide,

The interlayer insulating film 120 may be disposed on the cell substrate 100. The interlayer insulating film 120 may cover the mold structure MS. The interlayer insulating film 120 may include a first insulating film 120a and a second insulating film 120b. The second insulating film 120b may be disposed on the first insulating film 120a. The first insulating film 120a may cover the first structure MS1. The second insulating film 120b may cover the second structure MS2. Each of the first insulating film 120a and the second insulating film 120b may include, for example, at least one of silicon oxide, silicon oxynitride, or a low-k material having a lower dielectric constant than that of silicon oxide. However, the present disclosure is not limited thereto.

The channel structure CH may be disposed in the mold structure MS and in the first area R1. The channel structure CH may extend in the third direction Z as a vertical direction intersecting the top surface of the cell substrate 100 so as to extend through the mold structure MS. For example, the channel structure CH may have a pillar shape (e.g., a cylindrical shape) extending in the third direction Z. Accordingly, the channel structure CH may intersect each of the first gate electrodes ECL, GSL, and WL11 to WL1n, and the second gate electrodes WL21 to WL2n, and SSL.

In some example embodiments, the channel structure CH may include a first channel CH1, and a second channel CH2. The second channel CH2 may be disposed on the first channel CH1. For example, the first channel CH1 may be disposed in the first structure MS1, and the second channel CH2 may be disposed in the second structure MS2.

The channel structure CH may include a semiconductor pattern 130 and an information storage film 132.

The semiconductor pattern 130 may extend in the third direction Z so as to extend through the mold structure MS. The semiconductor pattern 130 is illustrated as having a shape of a cup. However, this is only illustrative. For example, the semiconductor pattern 130 may have various shapes (e.g., a cylindrical shape, a rectangular cylindrical shape, or a solid pillar shape). The semiconductor pattern 130 may include, but is not limited to, semiconductor materials such as single crystal silicon, polycrystalline silicon, organic semiconductor materials, and carbon nanostructures.

The information storage film 132 may be interposed between the semiconductor pattern 130 and each of the first and second gate electrodes ECL, GSL, WL11 to WL1n, WL21 to WL2n, and SSL. For example, the information storage film 132 may extend along an outer surface of the semiconductor pattern 130. The information storage film 132 may include, for example, at least one of silicon oxide, silicon nitride, silicon oxynitride, and a high dielectric constant material having a dielectric constant greater than that of silicon oxide. The high dielectric constant material may include, for example, at least one of aluminum oxide, hafnium oxide, lanthanum oxide, tantalum oxide, titanium oxide, lanthanum hafnium oxide, lanthanum aluminum oxide, dysprosium scandium oxide, and combinations thereof.

In some example embodiments, the plurality of channel structures CH may be arranged in a zigzag manner. For example, as illustrated in FIG. 3, the plurality of channel structures CH may be arranged in a staggered manner in each of the first direction X and the second direction Y. The plurality of channel structures CH arranged in the zigzag manner may further improve the integration of the non-volatile memory device. In some example embodiments, the plurality of channel structures CH may be arranged in a form of a honeycomb.

In some example embodiments, a dummy channel structure DCH may be formed in the mold structure MS and in the first sub-area S1. The dummy channel structure DCH may be formed in a shape similar to that of the channel structure CH so as to reduce stress applied to the mold structure MS in the first sub-area S1.

In some example embodiments, the information storage film 132 may be composed of a multilayer. For example, as shown in FIG. 7, the information storage film 132 may include a tunnel insulating film 132a, a charge storage film 132b, and a blocking insulating film 132c that are sequentially stacked on an outer surface of the semiconductor pattern 130.

The tunnel insulating film 132a may include, for example, silicon oxide or a high dielectric constant material having a higher dielectric constant than that of silicon oxide. The high dielectric constant material may include aluminum oxide (Al₂O₃), and hafnium oxide (HfO₂). The charge storage film 132b may include, for example, silicon nitride. The blocking insulating film 132c may include, for example, silicon oxide or a high dielectric constant material having a higher dielectric constant than that of silicon oxide. The high dielectric constant material may include aluminum oxide (Al₂O₃), and hafnium oxide (HfO₂).

In some example embodiments, the channel structure CH may further include a filling pattern 134. The filling pattern 134 may fill an inside of the cup-shaped semiconductor pattern 130. The filling pattern 134 may include an insulating material, for example, silicon oxide. However, the present disclosure is not limited thereto.

In some example embodiments, the channel structure CH may further include a channel pad 136. The channel pad 136 may be connected to the semiconductor pattern 130. For example, the channel pad 136 may be disposed in the interlayer insulating film 120 so as to be connected to a top of the semiconductor pattern 130. The channel pad 136 may include, for example, polysilicon doped with impurities. However, the present disclosure is not limited thereto.

In some example embodiments, a source layer 102 and a source support layer 104 may be sequentially formed on the cell substrate 100. The source layer 102 and the source support layer 104 may be interposed between the cell substrate 100 and the mold structure MS. For example, the source layer 102 and the source support layer 104 may extend along the top surface of the cell substrate 100.

In some example embodiments, the source layer 102 may be connected to the semiconductor pattern 130 of the channel structure CH. For example, as illustrated in FIG. 7, the source layer 102 may extend through the information storage film 132 so as to contact the semiconductor pattern 130. The source layer 102 may act as a common source line (e.g., CSL of FIG. 2) of the non-volatile memory device. The source layer 102 may include, for example, polysilicon doped with impurities or a metal. However, the present disclosure is not limited thereto.

In some example embodiments, the channel structure CH may extend through the source layer 102 and the source support layer 104. For example, the channel structure CH may extend through the source layer 102 and the source support layer 104 such that a bottom of the channel structure CH may be buried in the cell substrate 100.

In some example embodiments, the source support layer 104 may act as a support layer to mitigate or prevent collapse of the mold stack in a replacement process to form the source layer 102.

Although not shown, a base insulating film may be interposed between the cell substrate 100 and the source layer 102. The base insulating film may include, for example, at least one of silicon oxide, silicon nitride, or silicon oxynitride. However, the present disclosure is not limited thereto.

In some example embodiments, the insulating substrate 101 may be formed in the second area R2. The insulating substrate 101 may extend through the source layer 102 and the source support layer 104. It is illustrated that a top surface of the insulating substrate 101 is coplanar with a top surface of the source support layer 104. However, this is only an example. In another example, a vertical level of the top surface of the insulating substrate 101 may be higher than that of the top surface of the source support layer 104.

The block isolation area WLC may extend in the first direction X so as to cut the mold structure MS. The mold structure MS may be divided into portions via a plurality of block isolation areas WLC so as to form a plurality of memory cell blocks (e.g., BLK1 to BLKn of FIG. 1). For example, two adjacent block isolation areas WLC may define one memory cell block therebetween. The plurality of channel structures CH may be disposed in each of the memory cell blocks defined by the block isolation areas WLC.

In FIG. 4, it is illustrated that the number of the channel structures CH arranged in a zigzag along the second direction Y in one memory cell block is 9. However, this is only an example. In another example, the number of the channel structures CH arranged in each memory cell block is not limited to the illustrated one and may vary.

In some example embodiments, the block isolation area WLC may extend in the third direction Z to cut the source layer 102 and the source support layer 104. Although it is illustrated that a bottom surface of the block isolation area WLC is coplanar with a bottom surface of the source layer 102, this is only an example. In another example, a vertical level of the bottom surface of the block isolation area WLC may be lower than that of the bottom surface of the source layer 102.

In some example embodiments, the block isolation area WLC may include an insulating material. For example, the insulating material may fill the block isolation area WLC. The insulating material may include, for example, at least one of silicon oxide, silicon nitride, or silicon oxynitride. However, the present disclosure is not limited thereto.

In some example embodiments, a string isolation structure SC may be disposed in the second structure MS2. The string isolation structure SC may extend in the first direction X so as to cut the string select line SSL. Each of the memory cell blocks defined by the block isolation areas WLC may be divided into portions via the string isolation structure SC so as to form a plurality of string areas. For example, the string isolation structure SC may define two string areas in one memory cell block.

The bit-line BL may be formed on the mold structure MS and the interlayer insulating film 120. The bit-line BL may extend in the second direction Y so as to intersect the block isolation area WLC. Further, the bit-line BL may extend in the second direction Y so as to be connected to the plurality of channel structures CH arranged along the second direction Y. For example, a bit-line contact 162 connected to a top of each channel structure CH may be formed in the interlayer insulating film 120. The bit-line BL may be electrically connected to the channel structures CH via the bit-line contact 162.

The through-contacts TC1 and TC2 may be disposed on the substrate in the second area R2. In some embodiments, the through-contacts TC1 and TC2 includes the first through-contact TC1 and the second through-contact TC2. For example, the first through-contact TC1 may be a cell contact, and the second through-contact TC2 may be an input/output contact. The cell contact may be connected to a portion of the gate electrode, and the input/output contact may be connected to an input/output pad disposed outside the non-volatile memory device.

The first through-contact TC1 may be disposed on the substrate in the first sub-area S1. In the first sub-area S1, the first through-contact TC1 may extend in the third direction Z, and may extend through the mold structure MS. The first through-contact TC1 may extend through the interlayer insulating film 120 in the first sub-area S1. For convenience of description, it is illustrated that the number of the first through-contacts TC1 is five. However, the present disclosure is not limited thereto.

Top surfaces of the plurality of first through-contacts TC1 may be coplanar with each other. Further, bottom surfaces of the plurality of first through-contacts TC1 may be coplanar with each other. However, the present disclosure is not limited thereto.

The insulating ring 125 may be disposed in the mold structure MS. The insulating ring 125 may be interposed between the first through-contact TC1 and each of the first and second gate electrodes ECL, GSL, WL11 to WL1n, WL21 to WL2n, and SSL. The insulating ring 125 may be an annular structure surrounding the first through-contact TC1. The insulating ring 125 may electrically insulate some of the first and second gate electrodes ECL, GSL, WL11 to WL1n, WL21 to WL2n, and SSL, for example, non-selected gate electrodes and the first through-contact TC1 from each other. The non-selected gate electrode may be a gate electrode other than the selected gate electrode. The selected gate electrode may be a gate electrode connected to the first through-contact TC1.

For example, one of the first and second gate electrodes ECL, GSL, WL11 to WL1n, WL21 to WL2n, and SSL is connected to one the first through-contact TC1. The remaining gate electrodes among the first and second gate electrodes ECL, GSL, WL11 to WL1n, WL21 to WL2n, and SSL are electrically insulated from the first through-contact TC1 via the insulating ring 125.

The insulating ring 125 may electrically insulate other gate electrodes not exposed in the pad area among the first and second gate electrodes ECL, GSL, WL11 to WL1n, WL21 to WL2n, and SSL from the first through-contact TC1. For example, the insulating ring 125 may block or prevent the remaining gate electrodes except for the topmost gate electrode connected to the first through-contact TC1 from contacting the first through-contact TC1.

The insulating ring 125 may include an insulating material. The insulating ring 125 may include, for example, an oxide-based insulating material. In an example, the insulating ring 125 may include silicon oxide. However, the present disclosure is not limited thereto.

The second through-contact TC2 may be disposed on the substrate in the second sub-area S2. In the first sub-area S2, the second through-contact TC2 may extend in the third direction Z and may extend through the interlayer insulating film 120. For convenience of description, it is illustrated that the second through-contact TC2 is single. However, the present disclosure is not limited thereto.

Hereinafter, the second through-contact TC2 will be described in more detail with reference to FIG. 5. The first through-contact TC1 may be the same as or substantially to the second through-contact TC2.

In FIG. 5, the second through-contact TC2 may include a first portion 150 and a second portion 155. The second portion 155 may be disposed on the first portion 150.

In some example embodiments, the first portion 150 may be disposed within a first trench TR1. The first trench TR1 is disposed in the first insulating film 120a. A width of the first trench TR1 may gradually increase and then decrease as the first trench extends away from the insulating substrate 101. In other words, each of a width of a bottom of the first trench TR1 and a width of a top of the first trench TR1 is smaller than a width at a middle point of the first trench TR1.

In some example embodiments, the first portion 150 may be composed of multiple layers. For example, the first portion 150 may include a liner film 151 and a filling film 153. The liner film 151 may be disposed along a sidewall and a bottom surface of the first trench TR1. The filling film 153 may be disposed on the liner film 151. The filling film 153 may fill a remaining portion of the first trench TR1 after the liner film 151 has been disposed therein.

The liner film 151 includes a first sub-liner film 151a and a second sub-liner film 151b. The second sub-liner film 151b is disposed on the first sub-liner film 151a. The first sub-liner film 151a may be disposed along the sidewall and the bottom surface of the first trench TR1. The second sub-liner film 151b may be disposed along the first sub-liner film 151a.

The first sub-liner film 151a may include at least one of titanium nitride (TiN), tungsten nitride (WN), tungsten carbonitride (WCN), titanium silicon nitride (TSN), or tungsten (W) formed using physical vapor deposition (PVD). Fluorine (F) is not contained in the tungsten (W) formed using the PVD. The second sub-liner film 151b may be deposited using WF₆, B₂H₆, H₂, or SiH₄ gas. The second sub-liner film 151b may include, but is not limited to, boron (B) or silicon (Si).

In some example embodiments, the filling film 153 may be made of a multi grain conductive material. For example, the filling film 153 may include first to fourth areas 153a, 153b, 153c, and 153d. The first area 153a may be disposed on one sidewall of the first trench TR1. The second area 153b may be disposed on the other sidewall (e.g., an opposite sidewall) of the first trench TR1. The third area 153c may be disposed on the first area 153a. The fourth area 153d may be disposed on the second area 153b.

In some example embodiments, a boundary line BR may be formed at each of boundaries between the first to fourth areas 153a, 153b, 153c, and 153d. The filling film 153 may be formed using chemical vapor deposition (CVD). The filling film 153 may be grown using the liner film 151 as a seed film. At the boundary lines BR, the first to fourth areas 153a, 153b, 153c, and 153d of the filling film 153 may contact each other. The filling film 153 has been illustrated as including four areas. However, the present disclosure is not limited thereto. The filling film 153 may include a conductive material. The filling film 153 may include, but is not limited to, for example, metal such as tungsten (W), cobalt (Co), or nickel (Ni). For example, the filling film 153 may include tungsten (W).

In some example embodiments, the second portion 155 may be disposed within the second trench TR2. The second trench TR2 is disposed in the second insulating film 120b. A width of the second trench TR2 may gradually increase and then decrease as the second trench extends away from the insulating substrate 101. In other words, each of a width of a bottom of the second trench TR2 and a width of the top of the second trench TR2 is smaller than a width at a middle point of the second trench TR2.

In some example embodiments, the second portion 155 may be embodied as a single layer. The second portion 155 may be made of a single grain conductive material. The second portion 155 may be formed in a bottom-up manner. The ‘bottom-up’ manner may mean a manner in which a portion is formed from one surface in one direction. That is, the second portion 155 may be deposited from the first portion 150 in the third direction Z. The second portion 155 may include a conductive material. The second portion 155 may include, but is not limited to, a metal such as tungsten (W), cobalt (Co), or nickel (Ni). For example, the second portion 155 may include tungsten (W).

In some example embodiments, the first trench TR1 may overlap the first channel CH1 in the first direction X, and the second trench TR2 may overlap the second channel CH2 in the first direction X. In other words, the first portion 150 of the second through-contact TC2 may overlap the first channel CH1 in the first direction X, and the second portion 155 of the second through-contact TC2 may overlap the second channel CH2 in the first direction X. However, the present disclosure is not limited thereto.

Referring back to FIG. 4, each of the through-contacts TC1 and TC2 may be connected to a first wiring pattern 170 on the interlayer insulating film 120. For example, the first inter-wiring insulating film 140 may be disposed on the interlayer insulating film 120. The first wiring pattern 170 may be formed in the first inter-wiring insulating film 140 so as to be connected to each of the through-contacts TC1 and TC2. Each of the through-contacts TC1 and TC2 and the first wiring pattern 170 may be connected to each other via a first wiring contact 164. The first wiring pattern 170 may be connected to the bit-line BL. Each of the first wiring pattern 170 and the first wiring contact 164 may include a conductive material. For example, each of the first wiring pattern 170 and the first wiring contact 164 may include, but is not limited to, tungsten (W) or copper (Cu).

A peripheral circuit substrate 200 may be disposed below the cell substrate 100. For example, a top surface of the peripheral circuit substrate 200 may face the bottom surface of the cell substrate 100. The peripheral circuit substrate 200 may include, for example, a semiconductor substrate such as a silicon substrate, a germanium substrate, or a silicon-germanium substrate. In some example embodiments, the peripheral circuit substrate 200 may include a silicon-on-insulator (SOI) substrate or a germanium-on-insulator (GOI) substrate, etc.

A peripheral circuit element PT may be formed on the peripheral circuit substrate 200. The peripheral circuit element PT may constitute a peripheral circuit that controls an operation of the non-volatile memory device (e.g., 30 in FIG. 1). For example, the peripheral circuit element PT may include a control logic (e.g., 37 of FIG. 1), a row decoder (e.g., 33 of FIG. 1), and a page buffer (e.g., 35 of FIG. 1), etc. In following descriptions, a surface of the peripheral circuit substrate 200 on which the peripheral circuit element PT is disposed may be referred to as a front surface (front side) of the peripheral circuit substrate 200. Conversely, a surface of the peripheral circuit substrate 200 opposite to the front surface of the peripheral circuit substrate 200 may be referred to as a rear surface (back side) of the peripheral circuit substrate 200.

The peripheral circuit element PT may include, for example, a transistor. However, the present disclosure is not limited thereto. For example, the peripheral circuit element PT may include not only various active elements such as a transistor, but also various passive elements such as a capacitor, a resistor, and an inductor.

In some example embodiments, the rear surface of the cell substrate 100 may face the front surface of the peripheral circuit substrate 200. For example, a second inter-wiring insulating film 220 covering the peripheral circuit element PT may be formed on the front surface of the peripheral circuit substrate 200. The cell substrate 100 and/or the insulating substrate 101 may be stacked on a top surface of the second inter-wiring insulating film 220.

The first wiring pattern 170 may be connected to the peripheral circuit element PT via each of the first through-contact TC1 and the second through-contact TC2. For example, second wiring patterns 241 and 242 connected to the peripheral circuit element PT may be formed in the second inter-wiring insulating film 220. Each of the first through-contact TC1 and the second through-contact TC2 may extend through the interlayer insulating film 120 so as to connect the first wiring pattern 170 to the second wiring patterns 241 and 242. The second wiring patterns 241 and 242 may be connected to each other via second wiring contacts 232. Further, the second wiring patterns 241 and 242 may be electrically connected to the peripheral circuit element PT via the second wiring contacts 231 and 232. Thus, the bit-line BL, each of the first and second gate electrodes ECL, GSL, WL11 to WL1n, WL21 to WL2n, and SSL, and/or the source layer 102 may be electrically connected to the peripheral circuit element PT.

The peripheral circuit elements PT may be isolated from each other via a peripheral element isolation film 205. For example, the peripheral element isolation film 205 may be disposed in the peripheral circuit substrate 200. The peripheral element isolation film 205 may be embodied as a STI (shallow trench isolation) film. The peripheral element isolation film 205 may define active areas of the peripheral circuit elements PT. The peripheral element isolation film 205 may include an insulating material. The peripheral element isolation film 205 may include, for example, at least one of silicon nitride, silicon oxide, or silicon oxynitride.

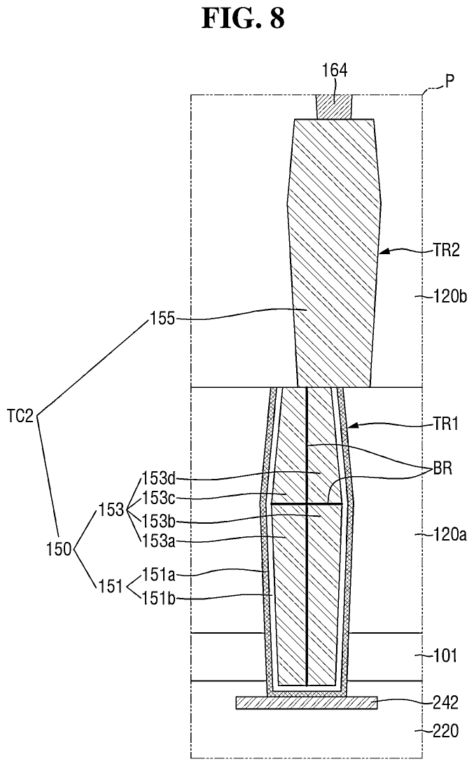

Hereinafter, various example embodiments of the non-volatile memory device of the present disclosure will be described with reference to FIG. 8 to FIG. 17. FIG. 8 to FIG. 11 are illustrative views of a through-contact according to some example embodiments. For convenience of description, following descriptions are based on differences thereof from those set forth above with reference to FIG. 1 to FIG. 7.

First, referring to FIG. 8, the first trench TR1 and the second trench TR2 may be positionally offset relative to each other.

A center of the first trench TR1 and a center of the second trench TR2 do not coincide with each other in the third direction Z. When the first trench TR1 is formed and then the second trench TR2 is formed, the center of the second trench TR2 may be positionally offset relative to the center of the first trench TR1. In this regard, at least a portion of the liner film 151 of the first portion 150 does not overlap the second portion 155 in the third direction Z. A portion of the filling film 153 of the first portion 150 may not overlap the second portion 155 in the third direction Z. However, the present disclosure is not limited thereto.

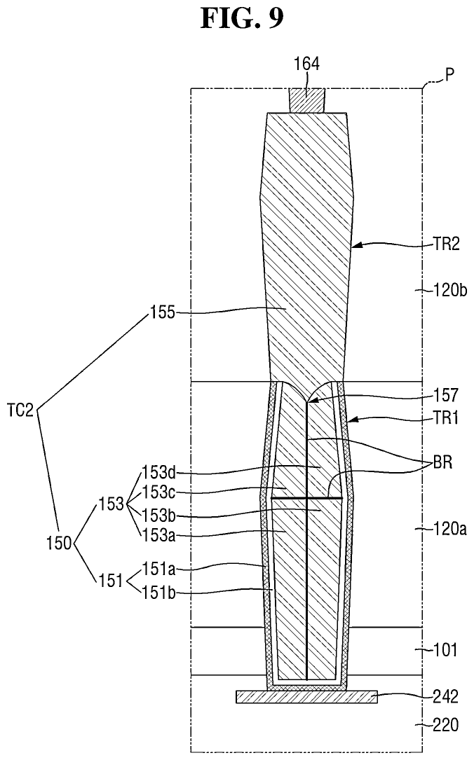

Referring to FIG. 9, the second through-contact TC2 according to an example embodiment may further include a tip portion 157. The tip portion 157 may be formed at a boundary between the first portion 150 and the second portion 155.

In some example embodiments, the tip portion 157 may be convex toward the insulating substrate 101. The tip portion 157 may be formed by causing the boundary between the second portion 155 and the first portion 150 to protrude in a direction from the second portion 155 toward the first portion 150. Accordingly, a portion of the second portion 155 may be disposed in the first trench TR1. The tip portion 157 may be connected to the boundary line BR. The boundary between the second portion 155 and the first portion 150 may be concave with respect to the insulating substrate 101. However, the present disclosure is not limited thereto.

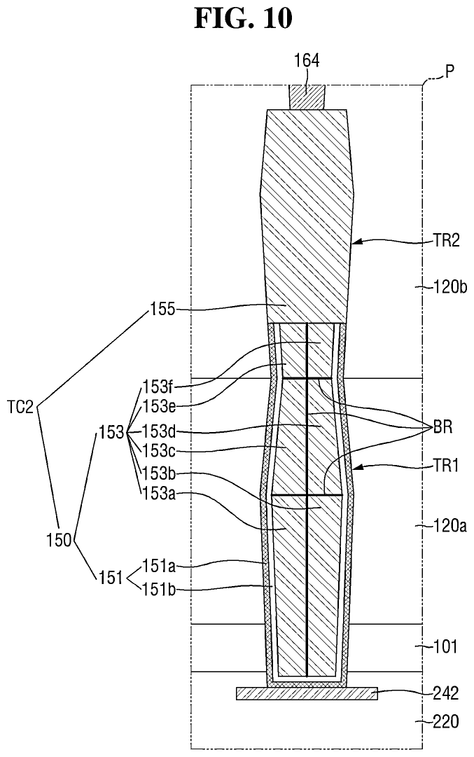

Referring to FIG. 10, a portion of the first portion 150 may be disposed in the second trench TR2. A portion of the liner film 151 may be disposed on a sidewall of the second trench TR2. A portion of the filling film 153 may be disposed in the second trench TR2. At least a portion of the first portion 150 overlaps the second interlayer insulating film 120b in the first direction X and/or the second direction Y. A top surface of the filling film 153 may be disposed at a higher vertical level than that of a top surface of the first interlayer insulating film 120a. In other words, a vertical spacing (e.g., distance or height) from the top surface of the insulating substrate 101 to the top surface of the filling film 153 in the third direction Z is greater than a vertical spacing (e.g., distance or height) from the top surface of the insulating substrate 101 to the top surface of the first interlayer insulating film 120a in the third direction Z.

In some example embodiments, the filling film 153 may further include a fifth area 153e and a sixth area 153f. The fifth area 153e is disposed on the third area 153c. The sixth area 153f is disposed on the fourth area 153d. Similarly, a boundary line BR may be formed at a boundary between the fifth area 153e and the sixth area 153f. Further, a boundary line BR may be formed at a boundary between the fifth area 153e and the third area 153c. A boundary line BR may be formed at a boundary between the sixth area 153f and the fourth area 153d.

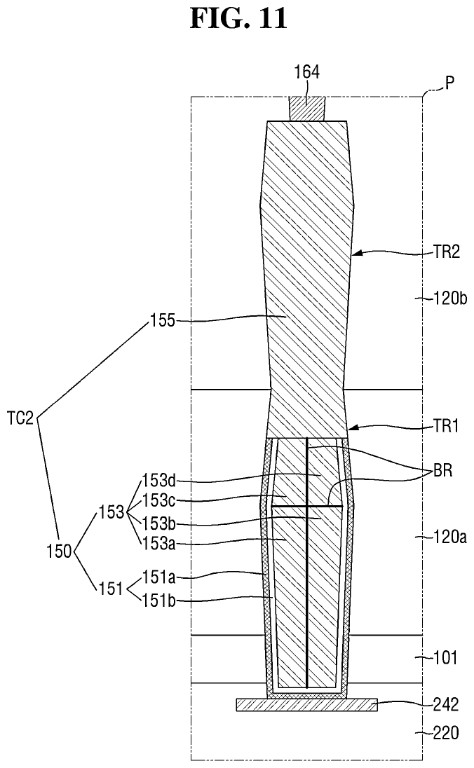

Referring to FIG. 11, at least a portion of the second portion 155 may be disposed in the first trench TR1. The liner film 151 of the first portion 150 is not disposed on a portion of the sidewall of the first trench TR1. The liner film 151 does not extend to a top of the sidewall of the first trench TR1. The filling film 153 does not fill an entirety of the first trench TR1. The top surface of the filling film 153 may be disposed at a lower vertical level than that of the top surface of the first interlayer insulating film 120a. In other words, the vertical spacing (e.g., distance or height) from the top surface of the insulating substrate 101 to the top surface of the filling film 153 in the third direction Z is smaller than the vertical spacing (e.g., distance or height) from the top surface of the insulating substrate 101 to the top surface of the first interlayer insulating film 120a in the third direction Z.

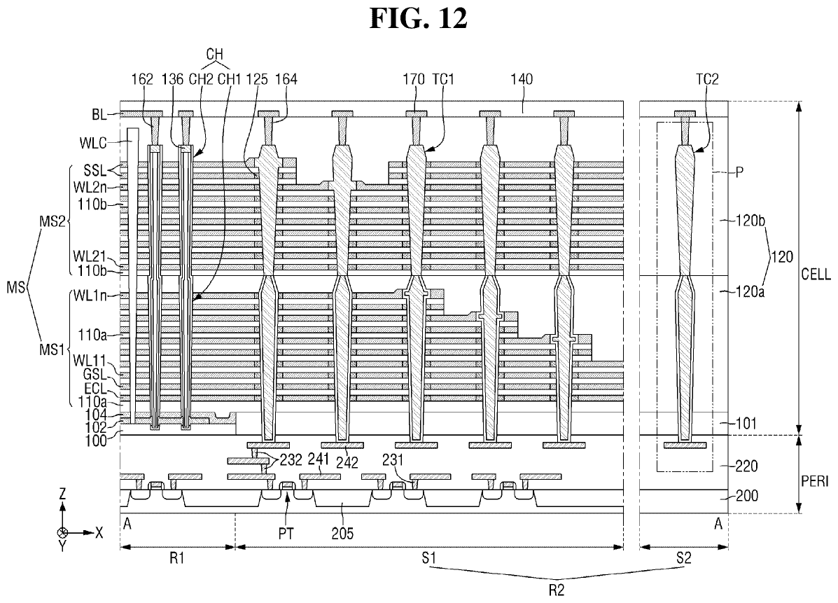

FIG. 12 is an illustrative diagram of a non-volatile memory device in accordance with an example embodiment. For convenience of description, following descriptions are based on differences thereof from those set forth above with reference to FIG. 1 to FIG. 7.

Referring to FIG. 12, the first gate electrodes ECL, GSL, and WL11 to WL1n may be stacked in a stepwise manner in the first sub-area S1, whereas the second gate electrodes WL21 to WL2n and SSL may not be stacked in a stepwise manner in the first sub-area S1.

In some example embodiments, a gate electrode connected to the first through-contact TC1 may not be the topmost gate electrode among the first gate electrodes ECL, GSL, and WL11 to WL1n, and the second gate electrodes WL21 to WL2n, and SSL. For example, in FIG. 12, the gate electrode connected to the first through-contact TC1 may be the topmost gate electrode among the first gate electrodes ECL, GSL, and WL11 to WL1n. In this case, the first through-contact TC1 may extend through the second gate electrodes WL21 to WL2n, and SSL. Further, the first through-contact TC1 may be insulated from the second gate electrodes WL21 to WL2n and SSL via the insulating ring 125. However, the present disclosure is not limited thereto.

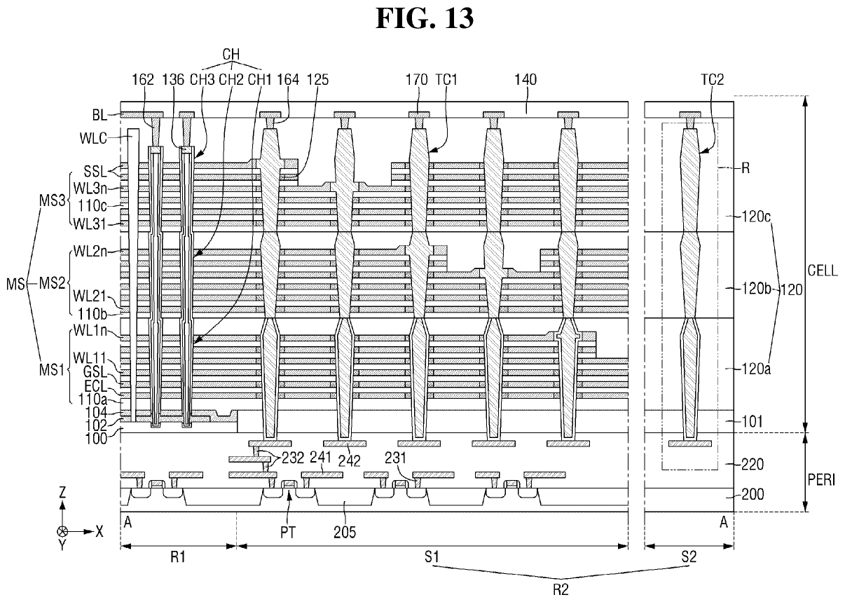

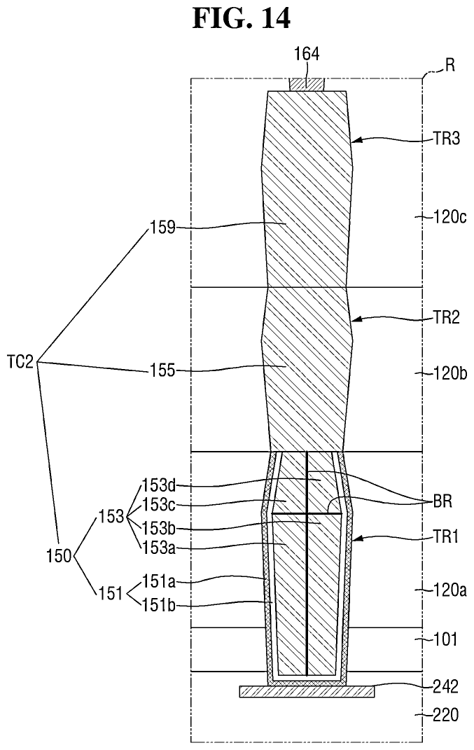

FIG. 13 is an illustrative diagram of a non-volatile memory device in accordance with an example embodiment. FIG. 14 is an enlarged view of a R area of FIG. 13. For convenience of description, following descriptions are based on differences thereof from those set forth above with reference to FIG. 1 to FIG. 7.

First, referring to FIG. 13, the non-volatile memory device according to an example embodiment may be a 3-stack non-volatile memory device. For example, the mold structure MS includes a first structure MS1, a second structure MS2, and a third structure MS3. The first structure MS1, the second structure MS2, and the third structure MS3 may be sequentially stacked in the third direction Z. The interlayer insulating film 120 includes first to third insulating films 120a, 120b, and 120c.

The first structure MS1 may include a plurality of first gate electrodes ECL, GSL, and WL11 to WL1n and a plurality of first mold insulating films 110a that are alternately stacked on top of each other while being disposed on the cell substrate 100. Each of the plurality of first gate electrodes ECL, GSL, and WL11 to WL1n and the plurality of first mold insulating films 110a may have a layer-like structure extending in a parallel manner to the top surface of the cell substrate 100. The first insulating film 120a may cover the first structure MS1.

The second structure MS2 may include a plurality of second gate electrodes WL21 to WL2n and a plurality of second mold insulating films 110b that are alternately stacked on top of each other while being disposed on the first structure MS1. Each of the plurality of second gate electrodes WL21 to WL2n and the plurality of second mold insulating films 110b may have a layer-like structure extending in a parallel manner to the top surface of the cell substrate 100. The second insulating film 120b may cover the second structure MS2.

The third structure MS3 may include a plurality of third gate electrodes WL31 to WL3n, and SSL and a plurality of third mold insulating films 110c that are alternately stacked on top of each other while being disposed on the second structure MS2. Each of the plurality of third gate electrodes WL31 to WL3n, and SSL, and the plurality of third mold insulating films 110c may have a layer-like structure extending in a parallel manner to the top surface of the cell substrate 100. The third insulating film 120c may cover the third structure MS3.

Each of the first gate electrodes ECL, GSL, and WL11 to WL1n, the second gate electrodes WL21 to WL2n, and the third gate electrodes WL31 to WL3n, and SSL may include a conductive material, for example, metal such as tungsten (W), cobalt (Co), nickel (Ni), or molybdenum (Mo) or a semiconductor material such as silicon. However, the present disclosure is not limited thereto.

Each of the first mold insulating film 110a, the second mold insulating film 110b, and the third mold insulating film 110c may include an insulating material, for example, at least one of silicon oxide, silicon nitride, or silicon oxynitride. However, the present disclosure is not limited thereto. In an example, each of the first mold insulating film 110a, the second mold insulating film 110b, and the third mold insulating film 110c may include silicon oxide.

Each of the first insulating film 120a, the second insulating film 120b, and the third insulating film 120c may include, for example, at least one of silicon oxide, silicon oxynitride, or a low-k material having a lower dielectric constant than that of silicon oxide. However, the present disclosure is not limited thereto.

In some example embodiments, the channel structure CH may include first to third channels CH1, CH2, and CH3. The first channel CH1 extends through the first structure MS1. The second channel CH2 extends through the second structure MS2. The third channel CH3 extends through the third structure MS3. The number of the channels included in the channel structure CH may be the same as the number of the stacks of the non-volatile memory device. However, the present disclosure is not limited thereto.

Subsequently, referring to FIG. 14, the second through-contact TC2 may include first to third portions 150, 155, and 159. The first to third portions 150, 155, and 159 may be sequentially arranged in the third direction Z. That is, the second portion 155 may be disposed between the first portion 150 and the third portion 159.

In some example embodiments, the first portion 150 may be disposed within the first trench TR1. The first trench TR1 is disposed in the first insulating film 120a. A width of the first trench TR1 may gradually increase and then decrease as the first trench extends away from the insulating substrate 101. In other words, each of a width of a bottom of the first trench TR1 and a width of a top of the first trench TR1 is smaller than a width at a middle point of the first trench TR1.

In some example embodiments, the second portion 155 may be disposed within the second trench TR2. The second trench TR2 is disposed in the second insulating film 120b. A width of the second trench TR2 may gradually increase and then decrease as the second trench extends away from the insulating substrate 101. In other words, each of a width of a bottom of the second trench TR2 and a width of a top of the second trench TR2 is smaller than a width at a middle point of the second trench TR2.

In some example embodiments, the third portion 159 may be disposed within a third trench TR3. The third trench TR3 is disposed in the third insulating film 120c. A width of the third trench TR3 may gradually increase and then decrease as the third trench extends away from the insulating substrate 101. In other words, each of a width of a bottom of the third trench TR3 and a width of a top of the third trench TR3 is smaller than a width at a middle point of the third trench TR3.

In some example embodiments, the third portion 159 may be embodied as a single layer. The third portion 159 may be made of a single grain conductive material. The third portion 159 may be formed in a bottom-up manner That is, the third portion 159 may be deposited from the second portion 155 in the third direction Z. The third portion 159 may include a conductive material. The third portion 159 may include, but is not limited to, metal such as tungsten (W), cobalt (Co), or nickel (Ni). In an example, the third portion 159 may include tungsten (W).

In some example embodiments, the first trench TR1 may overlap the first channel CH1 in the first direction X, the second trench TR2 may overlap the second channel CH2 in the first direction X, and the third trench TR3 may overlap the third channel CH3 in the first direction X. In other words, the first portion 150 of the second through-contact TC2 may overlap the first channel CH1 in the first direction X, the second portion 155 of the second through-contact TC2 may overlap the second channel CH2 in the first direction X, and the third portion 159 of the second through-contact TC2 may overlap the third channel CH3 in the first direction X. However, the present disclosure is not limited thereto.

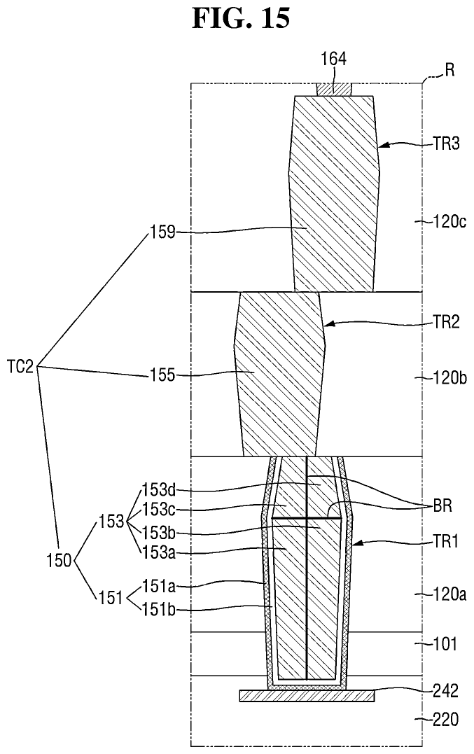

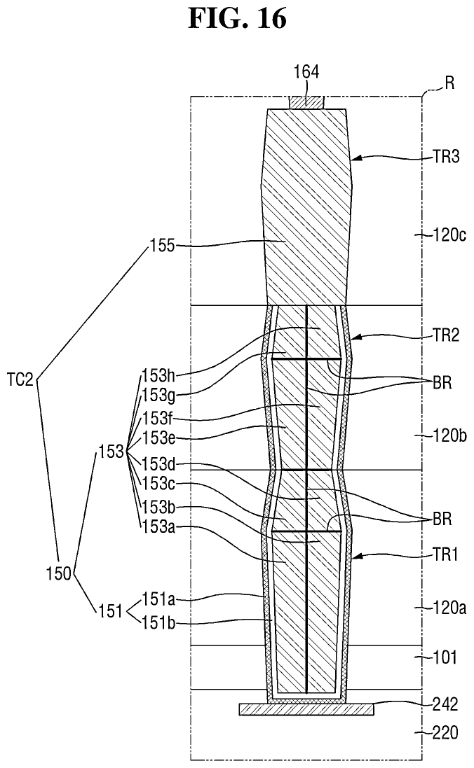

FIG. 15 and FIG. 16 are illustrative views of a through-contact in accordance with some example embodiments. For convenience of description, following descriptions are based on differences thereof from the description as set forth above with reference to FIG. 14.

First, referring to FIG. 15, the first trench TR1, the second trench TR2, and the third trench TR3 may be positionally offset relative to each other. A center of the first trench TR1 and a center of the second trench TR2 do not coincide with each other in the third direction Z. Further, the center of the second trench TR2 and a center of the third trench TR3 do not coincide with each other in the third direction Z. Further, the center of the first trench TR1 and the center of the third trench TR3 do not coincide with each other in the third direction Z. First, the first trench TR1 may be formed, then the second trench TR2 may be formed, and finally the third trench TR3 may be formed. Due to a nature of a process, the first trench TR1, the second trench TR2, and the third trench TR3 may be positionally offset relative to each other. However, unlike what is illustrated, only some of the first trench TR1, the second trench TR2, and the third trench TR3 may be positionally offset relative to each other. The present disclosure is not limited thereto.

Referring to FIG. 16, the first portion 150 may be disposed in the first trench TR1 and the second trench TR2. The second portion 155 may be disposed in the third trench TR3. The second portion 155 may be disposed on the first portion 150.

The liner film 151 may be disposed along a sidewall of the first trench TR1, a bottom surface of the first trench TR1, and a sidewall of the second trench TR2. The filling film 153 may fill a remaining portion of the first and second trenches TR1 and TR2 after the liner film 151 has been formed therein. The filling film 153 may include first to eighth areas 153a, 153b, 153c, 153d, 153e, 153f, 153g, and 153h. A boundary line BR may be formed at each of boundaries between the first to eighth areas 153a, 153b, 153c, 153d, 153e, 153f, 153g, and 153h.

The first to fourth areas 153a, 153b, 153c, and 153d are disposed in the first trench TR1. The fifth to eighth areas 153e, 153f, 153g, and 153h are disposed in the second trench TR2. For example, the fifth area 153e may be disposed on one sidewall of the second trench TR2. The sixth area 153f may be disposed on the other sidewall (e.g., an opposite sidewall) of the second trench TR2. The seventh area 153g may be disposed on the fifth area 153e. The eighth area 153f may be disposed on the sixth area 153f.

In some example embodiments, a boundary line BR may be formed at each of boundaries between the first to eighth areas 153a, 153b, 153c, 153d, 153e, 153f, 153g, and 153h. The filling film 153 may be deposited on the liner film 151 using chemical vapor deposition (CVD). At the boundary line BR, the first to eighth areas 153a, 153b, 153c, 153d, 153e, 153f, 153g, and 153h of the filling film 153 may contact each other.

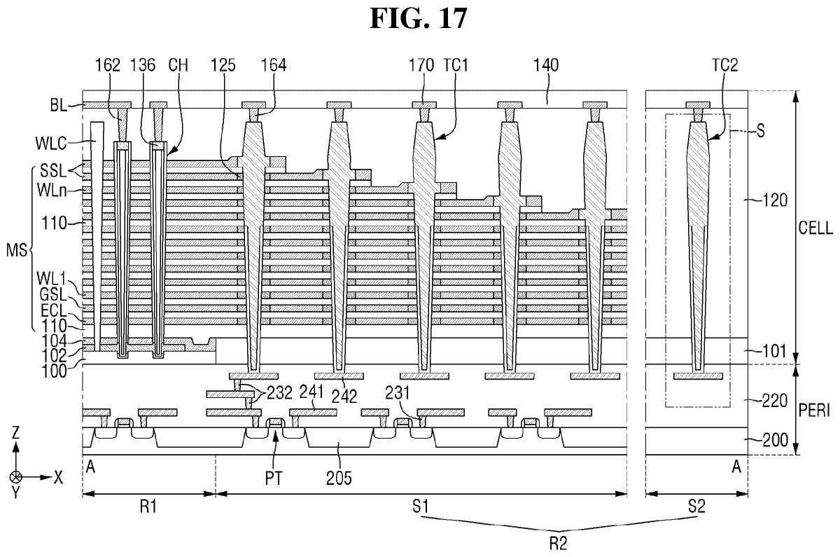

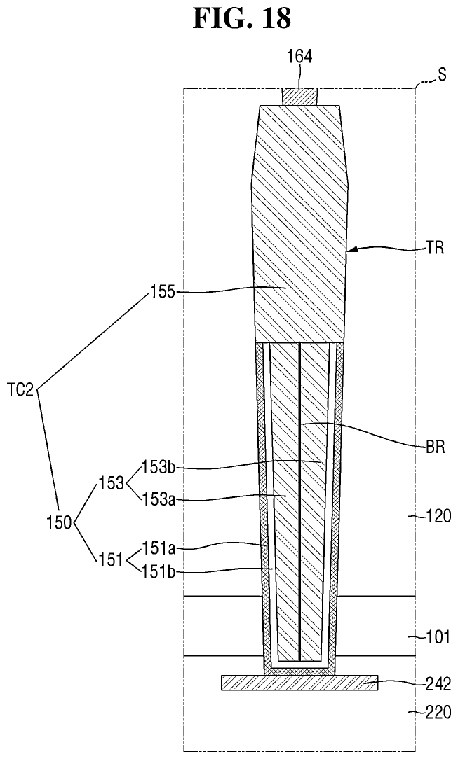

FIG. 17 is an illustrative diagram of a non-volatile memory device in accordance with an example embodiment. FIG. 18 is an enlarged view of a S area of FIG. 17. For convenience of description, following descriptions are based on differences thereof from those set forth above with reference to FIG. 1 to FIG. 7.

First, referring to FIG. 17, the non-volatile memory device according to an example embodiment may be a single stack non-volatile memory device. That is, each of the mold structure MS, the channel structure CH, and the interlayer insulating film 120 may be embodied as one stack.

The mold structure MS may be disposed on the front surface of the cell substrate 100, for example, on the top surface thereof. The mold structure MS may include a plurality of gate electrodes ECL, GSL, WL1 to WLn, and SSL and a plurality of mold insulating films 110 alternately stacked on top of each other while being disposed on the cell substrate 100. Each of the gate electrodes ECL, GSL, WL1 to WLn, and SSL and the mold insulating films 110 may have a layer-like structure extending in a parallel manner to the top surface of the cell substrate 100. The gate electrodes ECL, GSL, WL1 to WLn, and SSL may be sequentially stacked on the cell substrate 100 while being spaced apart from each other via the mold insulating films 110.

The gate electrodes ECL, GSL, WL1 to WLn, and SSL may be stacked in a stepwise manner in the first sub-area S1. For example, the gate electrodes ECL, GSL, WL1 to WLn, and SSL may extend so as to have different lengths in the first direction X and thus may be stacked in a stepwise manner. In some example embodiments, the gate electrodes ECL, GSL, WL1 to WLn, and SSL may extend so as to have different lengths in the second direction Y and thus may be stacked in a stepwise manner. Accordingly, each of the gate electrodes ECL, GSL, WL1 to WLn, and SSL may include a pad area (not shown) not covered with other gate electrodes. The pad area may mean an area in which the first through-contact TC1 and a corresponding one of the gate electrodes contact each other.

In some example embodiments, the gate electrodes ECL, GSL, WL1 to WLn, and SSL may include an erase control line ECL, a ground select line GSL, and a plurality of word-lines WL1 to WLn sequentially stacked on the cell substrate 100. In some other example embodiments, the erase control line ECL may be omitted.

The mold insulating films 110 may be stacked in a stepwise manner in the first sub-area S1. For example, the mold insulating films 110 may extend so as to have different lengths in the first direction X and thus may be stacked in a stepwise manner. In some example embodiments, the mold insulating films 110 may extend so as to have different lengths in the second direction Y and thus may be stacked in a stepwise manner.

Each of the gate electrodes ECL, GSL, WL1 to WLn, and SSL may include a conductive material, for example, metal such as tungsten (W), cobalt (Co), nickel (Ni), molybdenum (Mo), or a semiconductor material such as silicon. However, the present disclosure is not limited thereto. For example, each of the gate electrodes ECL, GSL, WL1 to WLn, and SSL may include tungsten (W) or molybdenum (Mo). Unlike what is illustrated, each of the gate electrodes ECL, GSL, WL1 to WLn, and SSL may be embodied as multiple layers. For example, when each of the gate electrodes ECL, GSL, WL1 to WLn, and SSL is embodied as multi-layers, each of the gate electrodes ECL, GSL, WL1 to WLn, and SSL may include a gate electrode barrier film and a gate electrode filling film. The gate electrode barrier film may include, for example, titanium nitride (TiN), and the gate electrode filling film may include tungsten (W). However, the present disclosure is not limited thereto. For example, each of the gate electrodes ECL, GSL, WL1 to WLn, and SSL may include tungsten (W).

The mold insulating film 110 may include an insulating material, for example, at least one of silicon oxide, silicon nitride, or silicon oxynitride. However, the present disclosure is not limited thereto. In an example, the mold insulating film 110 may include silicon oxide.

Referring to FIG. 18, the second through-contact TC2 may be disposed in a trench TR. The trench TR may be formed in the interlayer insulating film 120. The second through-contact TC2 includes the first portion 150 and the second portion 155. The first portion 150 may be disposed in a lower portion of the trench TR. The second portion 155 may be disposed in an upper portion of the trench TR.

The first portion 150 includes the liner film 151 and the filling film 153. The liner film 151 is disposed along a portion of a sidewall of the trench TR. The liner film 151 does not extend to a top of the sidewall of the trench TR. That is, the liner film 151 is not disposed on at least a portion of the sidewall of the trench TR. The filling film 153 is disposed on the liner film 151. A top surface of the liner film 151 and a top surface of the filling film 153 may be coplanar with each other. However, the present disclosure is not limited thereto.

The filling film 153 may include a first area 153a and a second area 153b. The first area 153a is disposed on one sidewall of the trench TR. The second area 153b is disposed on the other sidewall (e.g., an opposite sidewall) of the trench TR. A boundary line BR may be formed at a boundary between the first area 153a and the second area 153b. That is, the filling film 153 may be made of a multi-grain conductive material.

The second portion 155 is disposed on the first portion 150. The second portion 155 may be made of a single grain conductive material. The second portion 155 may be formed in a bottom-up manner.

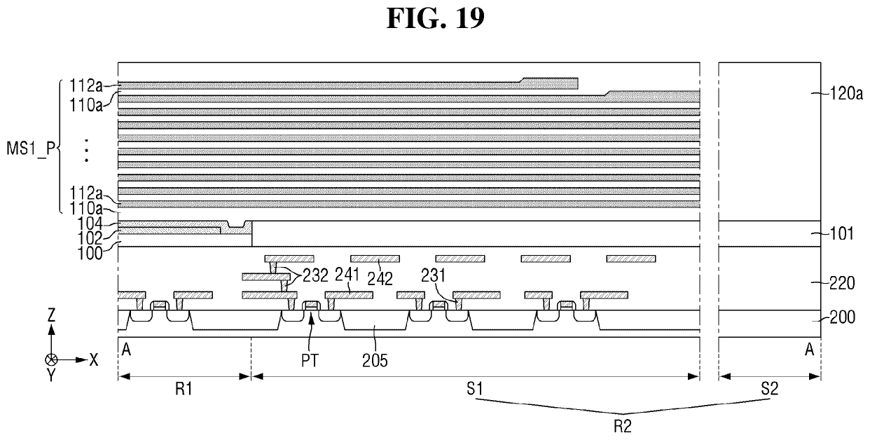

Hereinafter, a method for manufacturing a non-volatile memory device according to an example embodiment of the present disclosure will be described with reference to FIG. 19 to FIG. 33. FIG. 19 to FIG. 33 are diagrams for illustrating a method for manufacturing a non-volatile memory device according to an example embodiment.

Referring to FIG. 19, the peripheral circuit structure PERI may be formed. First, the peripheral circuit substrate 200 is provided. In the peripheral circuit substrate 200, the element isolation film 205 may be formed. The peripheral circuit element PT may be formed on the peripheral circuit substrate 200. The second inter-wiring insulating film 220 covering the peripheral circuit element PT may be formed on the peripheral circuit substrate 200. The second wiring patterns 241 and 242 and the second wiring contacts 231 and 232 may be formed in the second inter-wiring insulating film 220.

Subsequently, the cell substrate 100 and the insulating substrate 101 may be formed on the peripheral circuit structure PERI. The source layer 102 and the source support layer 104 may be formed on the cell substrate 100.

On the cell substrate 100 and the insulating substrate 101, a pre-first structure MS1_P may be formed. The pre-first structure MS1_P may include the plurality of first mold insulating films 110a and a plurality of first mold sacrificial films 112a that are alternately stacked on top of each other while being disposed on the cell substrate 100 and the insulating substrate 101. Each of the plurality of first mold insulating films 110a and the plurality of first mold sacrificial films 112a may have a layer-like structure extending in a parallel manner to the top surface of the substrate.

The first mold sacrificial film 112a may be made of a material having an etch selectivity relative to a material of the first mold insulating film 110a. For example, the first mold sacrificial film 112a may include a nitride-based insulating material. In an example, the first mold sacrificial film 112a may include, but is not limited to, silicon nitride.

Subsequently, the first insulating film 120a may be formed. The first insulating film 120a may cover the pre-first structure MS1_P.

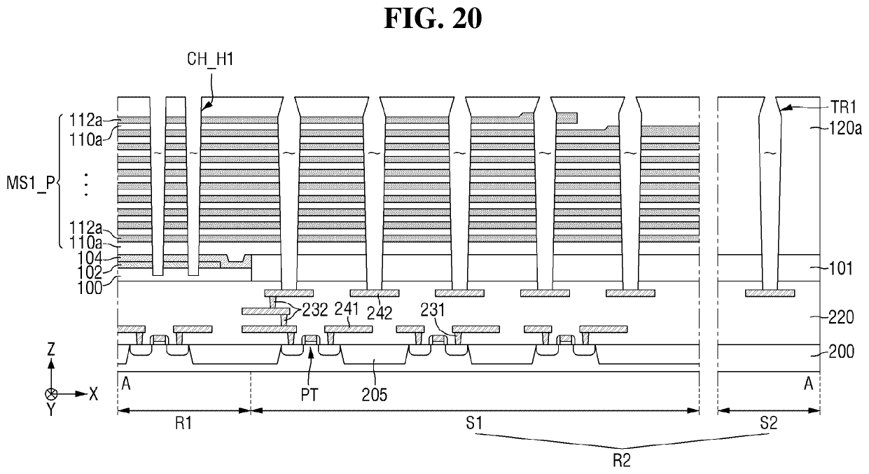

Referring to FIG. 20, a first channel hole CH_H1, and the first trench TR1 may be formed. The first channel hole CH_H1 may be formed on the substrate in the first area R1. The first channel hole CH_H1 may extend through the pre-first structure MS1_P. The first trench TR1 may be formed on the substrate in the second area R2. The first trench TR1 may extend through the pre-first structure MS1_P and the first insulating film 120a. Further, the first trench TR1 may extend through the insulating substrate 101. In some example embodiments, a width of the first trench TR1 may increase and then decrease as the first trench extends away from the top surface of the substrate.

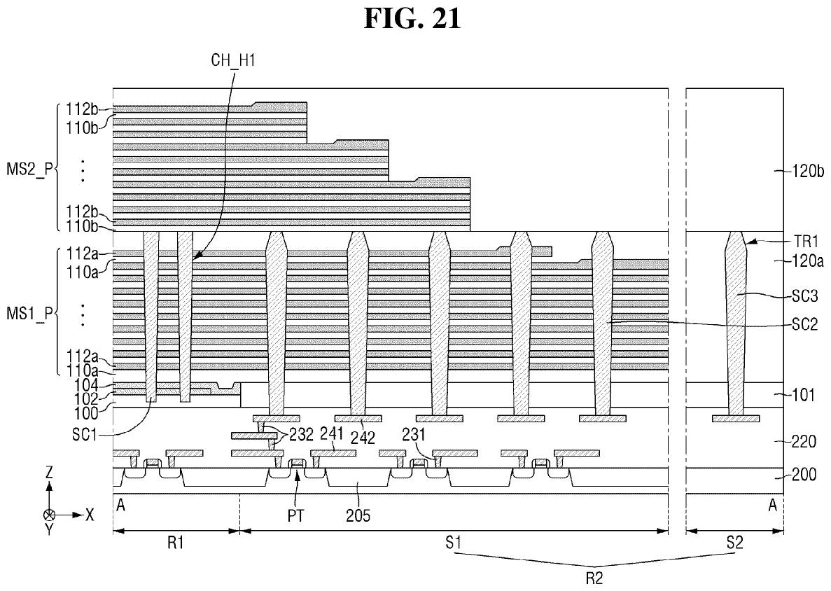

Referring to FIG. 21, a first sacrificial layer SC1 may be formed in the first channel hole CH_H1. The first sacrificial layer SC1 may fill the first channel hole CH_H1. A second sacrificial layer SC2 may be formed in the first trench TR1 in the first sub-area S1. The second sacrificial layer SC2 may fill the first trench TR1 in the first sub-area S1. A third sacrificial layer SC3 may be formed in the first trench TR1 in the second sub-area S2. The third sacrificial layer SC3 may fill the first trench TR1 in the second sub-area S2. Each of the first sacrificial layer SC1, the second sacrificial layer SC2, and the third sacrificial layer SC3 may be made of a polysilicon layer. However, the present disclosure is not limited thereto.

Subsequently, a pre-second structure MS2_P may be formed on the pre-first structure MS1_P.

The pre-second structure MS2_P may include the plurality of second mold insulating films 110b and a plurality of second mold sacrificial films 112b alternately stacked on top of each other while being disposed on the pre-first structure MS1_P. Each of the plurality of second mold insulating films 110b and the plurality of second mold sacrificial films 112b may have a layer-like structure extending in a parallel manner to the top surface of the substrate.

The second mold sacrificial film 112b may be made of a material having an etch selectivity relative to a material of the second mold insulating film 110b. For example, the second mold sacrificial film 112b may include a nitride-based insulating material. In an example, the second mold sacrificial film 112b may include, but is not limited to, silicon nitride.

Subsequently, the second insulating film 120b may be formed. The second insulating film 120b may cover the pre-second structure MS2_P.

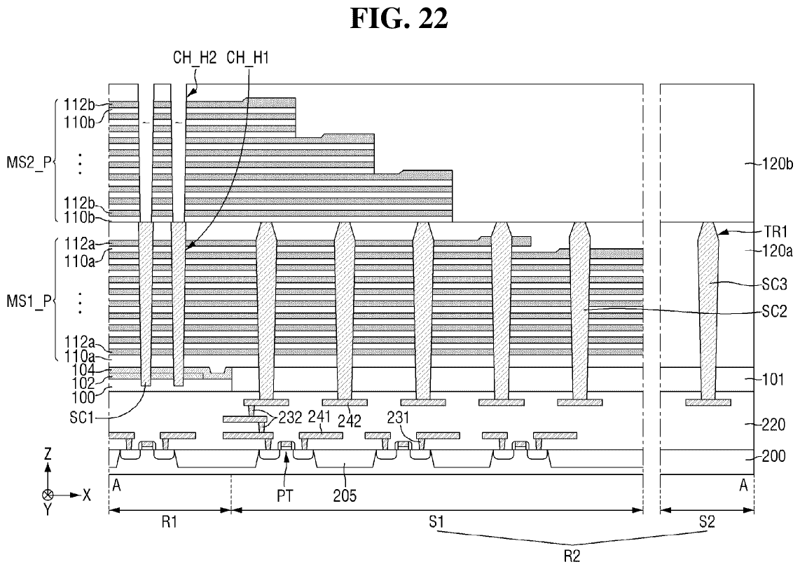

Referring to FIG. 22, a second channel hole CH_H2 may be formed. The second channel hole CH_H2 may be formed on the substrate in the first area R1. The second channel hole CH_H2 may extend through the pre-second structure MS2_P. The second channel hole CH_H2 may expose a top surface of the first sacrificial layer SC1. Due to a nature of a process, the second channel hole CH_H2 and the first channel hole CH_H1 may be positionally offset relative to each other.

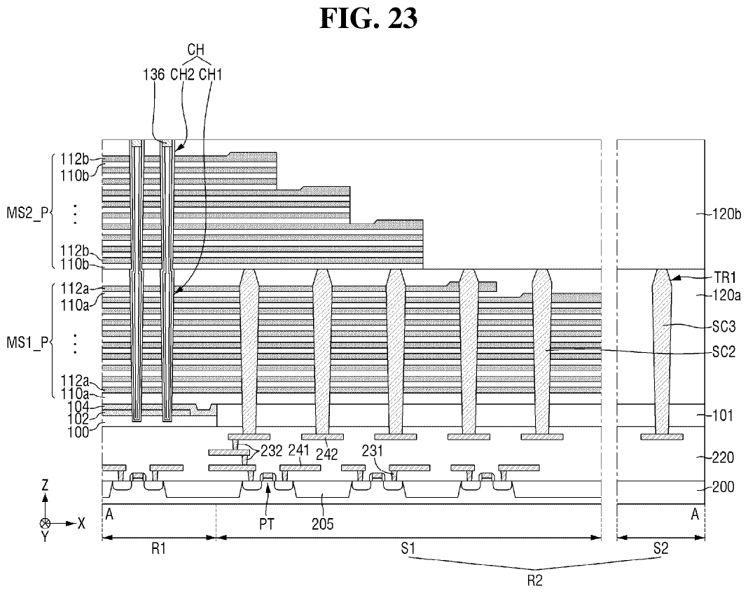

Referring to FIG. 23, the channel structure CH may be formed. The channel structure CH includes the first channel CH1 and the second channel CH2. First, the first sacrificial layer SC1 in the first channel hole CH_H1 may be removed. Subsequently, the first channel CH1 may be formed in the first channel hole CH_H1. The second channel CH2 may be formed in the second channel hole CH_H2.

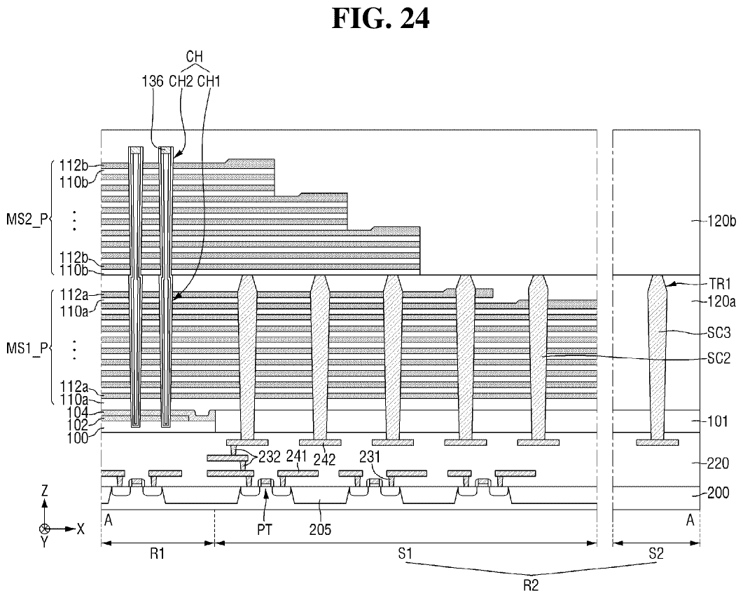

Referring to FIG. 24, an insulating layer covering the channel structure CH may be formed. The insulating layer may cover the second insulating film 120b. A material of the insulating layer is the same as the material of the second insulating film 120b. Hereinafter, an example in which the insulating layer is included in the second insulating film 120b will be described.

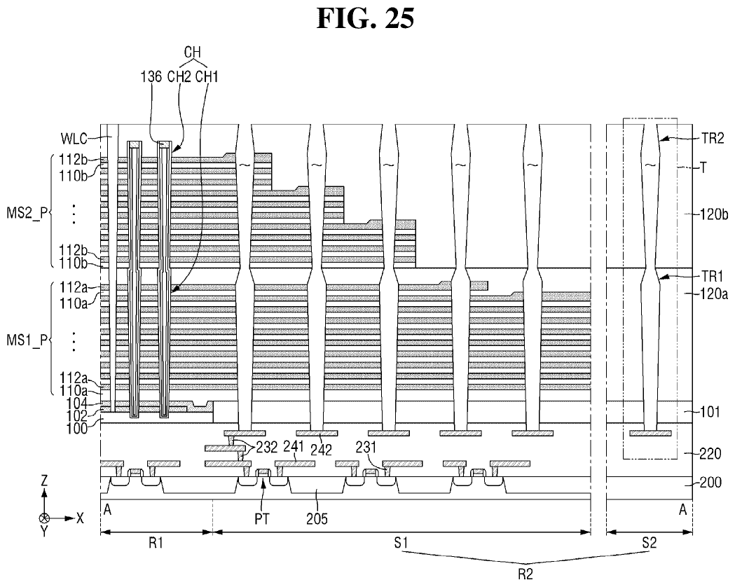

Referring to FIG. 25, the block isolation area WLC may be formed. The block isolation area WLC may extend through the pre-first structure MS1_P and the pre-second structure MS2_P.

Further, the second trench TR2 may be formed. The second trench TR2 may be formed on the substrate in the second area R2. The second trench TR2 is formed on the first trench TR1. Although not shown, the second trench TR2 may expose a top surface of each of the second sacrificial layer SC2 and the third sacrificial layer SC3. For example, in the first sub-area S1, the second trench TR2 exposes the top surface of the second sacrificial layer SC2. In the second sub-area S2, the second trench TR2 exposes the top surface of the third sacrificial layer SC3. After the second trench TR2 has been formed, the second sacrificial layer SC2 and the third sacrificial layer SC3 may be removed. Due to a nature of a process, the second trench TR2 may be positionally offset relative to the first trench TR1. However, the present disclosure is not limited thereto.

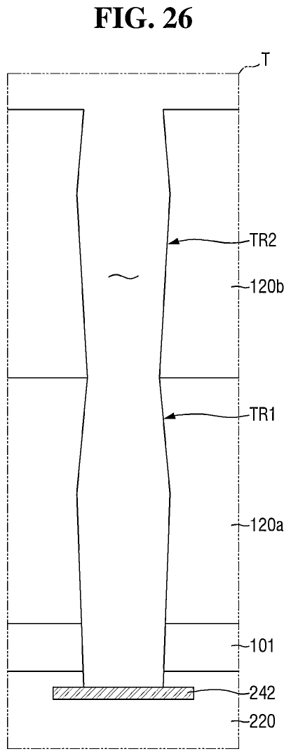

FIG. 26 to FIG. 33 are drawings to illustrate a method for manufacturing a through-contact. FIG. 26 to FIG. 33 may be enlarged views of a T area of FIG. 25.

Referring to FIG. 26, the width of the first trench TR1 may increase and then decrease as the first trench extends away from the insulating substrate 101. Similarly, the width of the second trench TR2 may increase and then decrease as the second trench extends away from the insulating substrate 101. The first trench TR1 may be disposed in the first insulating film 120a, and the second trench TR2 may be disposed in the second insulating film 120b.

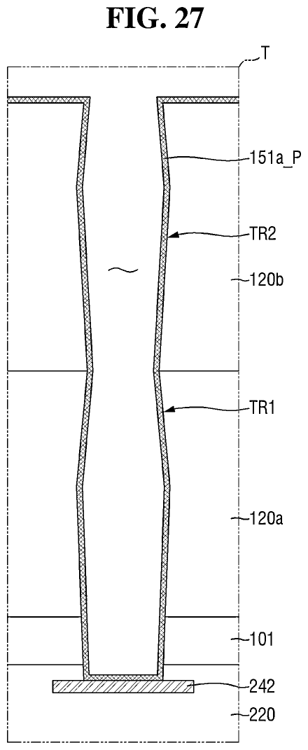

Referring to FIG. 27, a pre-first sub-liner film 151a_P may be formed. The pre-first sub-liner film 151a_P may be formed along the sidewall of the first trench TR1, the bottom surface of the first trench TR1, the sidewall of the second trench TR2, and the top surface of the second insulating film 120b. The pre-first sub-liner film 151a_P may include at least one of titanium nitride (TiN), tungsten nitride (WN), tungsten carbonitride (WCN), titanium silicon nitride (TSN), or tungsten (W) formed using the physical vapor deposition (PVD). Fluorine (F) is not contained in the tungsten (W) formed using the PVD.

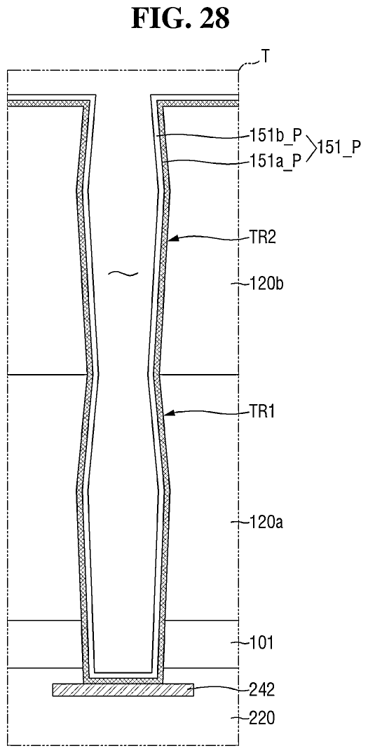

Referring to FIG. 28, a pre-liner film 151_P may be formed along the sidewall of the first trench TR1, the bottom surface of the first trench TR1, and the sidewall of the second trench TR2.

First, on the pre-first sub-liner film 151a_P, a pre-second sub-liner film 151b_P may be formed. The pre-first sub-liner film 151a_P and the pre-second sub-liner film 151b_P may constitute the pre-liner film 151_P. That is, the pre-liner film 151_P may include the pre-first sub-liner film 151a_P and the pre-second sub-liner film 151b_P. The pre-second sub-liner film 151b_P may be deposited using WF₆, B₂H₆, H₂, or SiH₄ gas. The pre-second sub-liner film 151b_P may include, but is not limited to, boron (B) or silicon (Si).

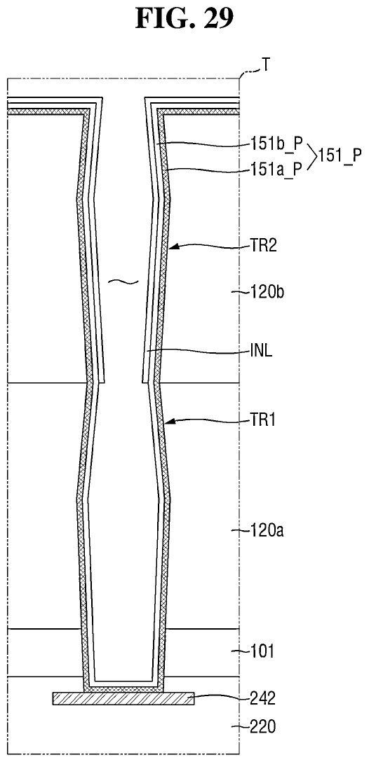

Referring to FIG. 29, an inhibiting layer INL may be formed. The inhibiting layer INL may be formed on the sidewall of the second trench TR2. The inhibiting layer INL may not be formed on the sidewall of the first trench TR1. The inhibiting layer INL may be formed on a portion of the pre-liner film 151_P on the sidewall of the second trench TR2. The inhibiting layer INL may not be formed on a portion of the pre-liner film 151_P on the sidewall of the first trench TR1.

The inhibiting layer INL may be formed using N₂ gas, NF₃ gas, NH₃ gas, or a combination thereof. For example, the inhibiting layer INL may be composed of a tungsten nitride (WN) film. In some example embodiments, the inhibiting layer INL may be made of tungsten (W) containing boron (B).

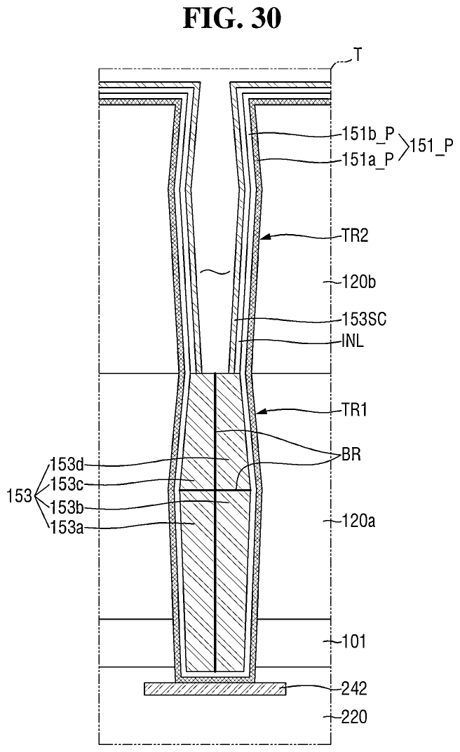

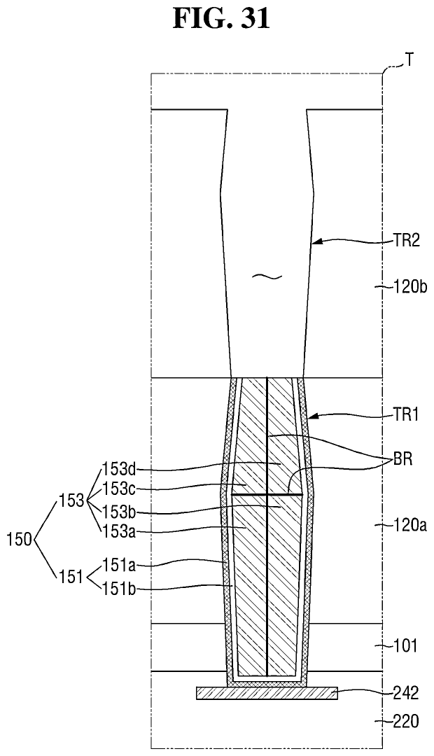

Referring to FIG. 30 (as well as FIG. 31), the filling film 153 and a filling sacrificial film 153SC may be formed. The filling film 153 is formed in the first trench TR1. The filling film 153 is formed on the liner film 151. The filling film 153 may be formed using the chemical vapor deposition (CVD). The filling film 153 may be grown using the liner film 151 as a seed film. The filling film 153 may be uniformly grown on one sidewall, the other sidewall (e.g., an opposite sidewall) and the bottom surface of the first trench TR1. Accordingly, the boundary line BR may be formed in the filling film 153. For example, the first area 153a and the third area 153c may be grown on one sidewall of the first trench TR1. The second area 153b and the fourth area 153d may be grown on the other sidewall (e.g., an opposite sidewall) of the first trench TR1. At the boundary line BR, the first to fourth areas 153a, 153b, 153c, and 153d contact each other.

That is, the filling film 153 may be embodied as a multi-grain film. The filling film 153 may be made of a multi-grain conductive material.

The filling sacrificial film 153SC may be formed in the second trench TR2. The filling sacrificial film 153SC may be formed on the inhibiting layer INL. The filling sacrificial film 153SC may be formed using the chemical vapor deposition (CVD) which is the case for the filling film 153. The filling sacrificial film 153SC may be grown with the inhibiting layer INL as a seed film. When the inhibiting layer INL is used as the seed film, a growth rate of the filling sacrificial film 153SC may be low. For example, the growth rate of the filling sacrificial film 153SC may be lower than a growth rate of the filling film 153. Therefore, while the filling film 153 fills an entirety of the first trench TR1, the filling sacrificial film 153SC does not fill an entirety of the second trench TR2.

Referring to FIG. 31, the filling sacrificial film 153SC, the inhibiting layer INL and the pre-liner film 151_P in the second trench TR2 may be removed.

The pre-liner film 151_P may be removed to form the liner film 151. The liner film 151 extends along the sidewall and the bottom surface of the first trench TR1, and does not extend along the sidewall of the second trench TR2.

The first portion 150 of the second through-contact may be formed. The first portion 150 may include the liner film 151 and the filling film 153.

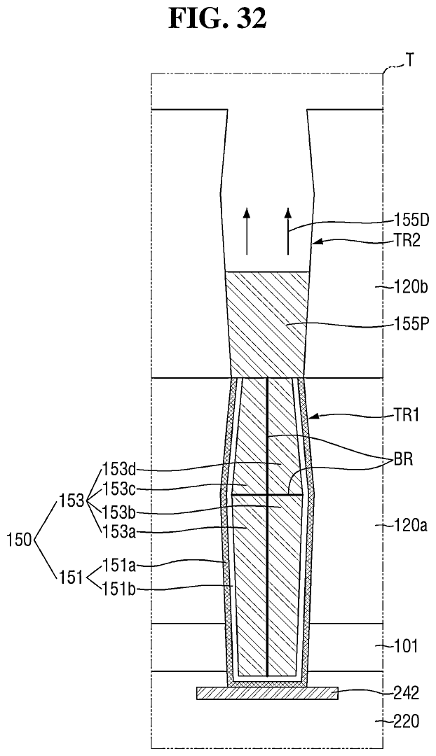

Referring to FIG. 32, a pre-second portion 155P may be formed. The pre-second portion 155P may be formed in a bottom-up manner. The bottom-up′ manner may mean a manner in which a portion is formed from one surface in one direction. The pre-second portion 155P may be grown in one direction in the bottom-up manner (see a reference numeral 155D). The pre-second portion 155P may be grown from the first portion 150 in the third direction Z. The pre-second portion 155P may be formed using the chemical vapor deposition (CVD).

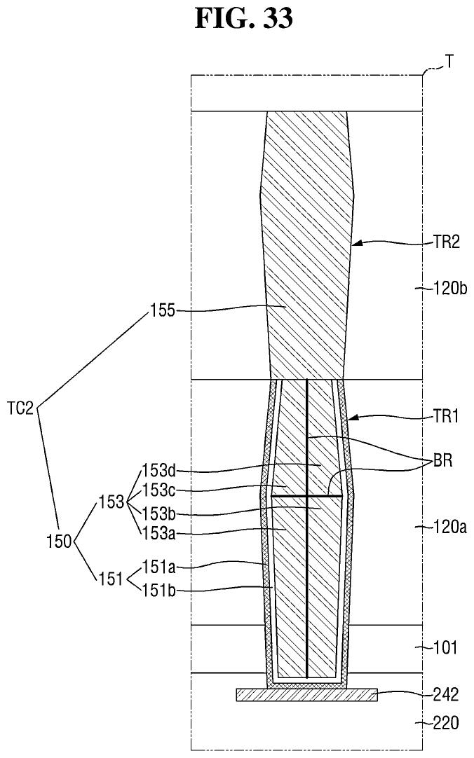

Referring to FIG. 33, the second portion 155 may be formed. That is, the second through-contact TC2 may be formed. The second through-contact TC2 includes the first portion 150 and the second portion 155.

The second portion 155 may fill the second trench TR2. As the second portion 155 is formed in the bottom-up manner, the second portion 155 may be made of a single grain material. For example, the second portion 155 may be made of a single grain conductive material.

When the method for manufacturing the non-volatile memory device according to the above example embodiment is used, the through-contact may be formed more effectively in a structure in which the number of the stacks is two or larger. Further, in a structure with a high aspect ratio, the through-contact may be formed more effectively.

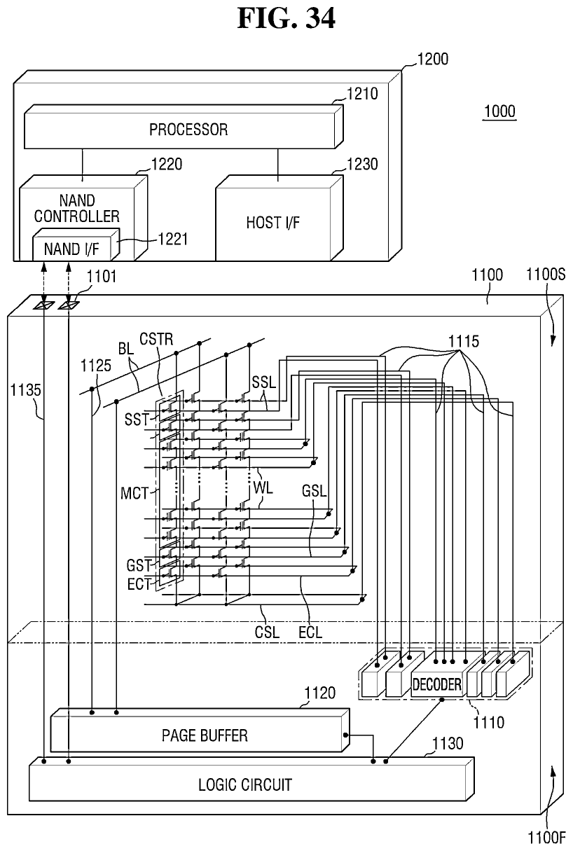

Hereinafter, an electronic system including a non-volatile memory device according to some example embodiments will be described with reference to FIG. 1 to FIG. 7, and FIG. 34 to FIG. 36.

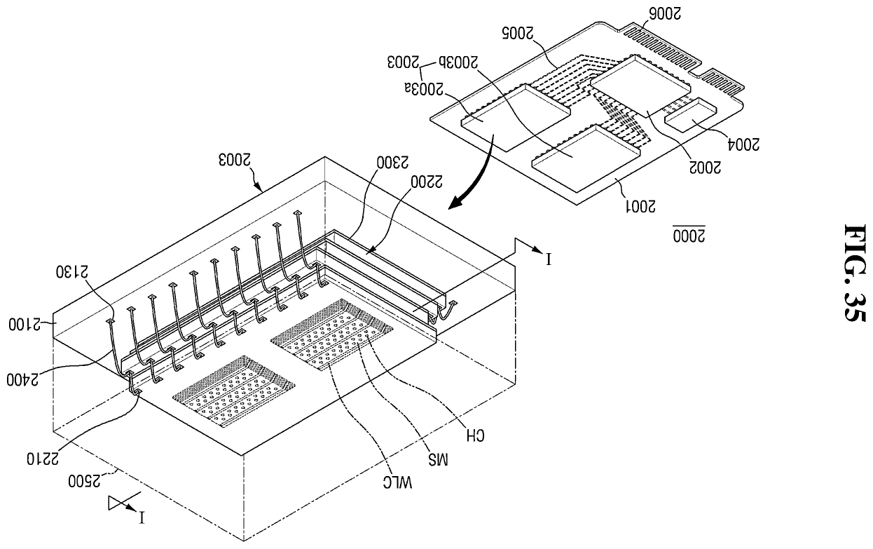

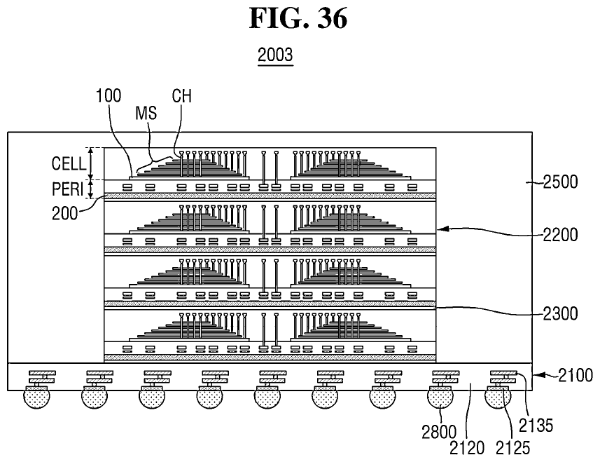

FIG. 34 is an illustrative block diagram for illustrating an electronic system according to an example embodiment. FIG. 35 is an illustrative perspective view for illustrating an electronic system according to an example embodiment. FIG. 36 is a schematic cross-sectional view taken along a line I-I of FIG. 35.

Referring to FIG. 34, an electronic system 1000 according to an example embodiment may include a non-volatile memory device 1100 and a controller 1200 electrically connected to the non-volatile memory device 1100. The electronic system 1000 may be a storage device including one or a plurality of non-volatile memory devices 1100 or an electronic device including the storage device. For example, the electronic system 1000 may be embodied as a solid state drive device (SSD), a Universal Serial Bus (USB), a computing system, a medical device, or a communication device including one or a plurality of non-volatile memory devices 1100.

The non-volatile memory device 1100 may be embodied, for example, as a NAND flash memory device and may include, for example, the non-volatile memory device as described above with reference to FIGS. 1 to 7. The non-volatile memory device 1100 may include a first structure 1100F and a second structure 1100S on the first structure 1100F.

The first structure 1100F may be a peripheral circuit structure including a decoder circuit 1110 (e.g., the row decoder 33 in FIG. 1), the page buffer 1120 (e.g., the page buffer 35 in FIG. 1), and a logic circuit 1130 (e.g., the control logic 37 of FIG. 1).

The second structure 1100S may include the common source line CSL, the plurality of bit-lines BL, and the plurality of cell strings CSTR as described above with reference to FIG. 2. The cell strings CSTR may be connected to the decoder circuit 1110 via the word-line WL, at least one string select line SSL, and at least one ground select line GSL. Further, the cell strings CSTR may be connected to the page buffer 1120 via the bit-lines BL.

In some example embodiments, the common source line CSL and the cell strings CSTR may be electrically connected to the decoder circuit 1110 via first connection lines 1115 extending from the first structure 1100F to the second structure 1100S.

In some example embodiments, the bit-lines BL may be electrically connected to the page buffer 1120 via second connection lines 1125 extending from the first structure 1100F to the second structure 1100S.

The non-volatile memory device 1100 may communicate with the controller 1200 via an input/output pad 1101 electrically connected to the logic circuit 1130 (e.g., the control logic 37 in FIG. 1). The input/output pad 1101 may be electrically connected to the logic circuit 1130 via an input/output connection line 1135 extending from the first structure 1100F to the second structure 1100S.

The controller 1200 may include a processor 1210, a NAND controller 1220, and a host interface 1230. In some embodiments, the electronic system 1000 may include a plurality of non-volatile memory devices 1100. In this case, the controller 1200 may control the plurality of non-volatile memory devices 1100.

The processor 1210 may control overall operations of the electronic system 1000 including the controller 1200. The processor 1210 may operate based on predefined firmware, and may control the NAND controller 1220 to access the non-volatile memory device 1100. The NAND controller 1220 may include a NAND interface 1221 that processes communication with the non-volatile memory device 1100. Via the NAND interface 1221, a control command for controlling the non-volatile memory device 1100, data to be written to memory cell transistors MCT of the non-volatile memory device 1100, and data to be read from the memory cell transistors MCT of the non-volatile memory device 1100 may be transmitted. The host interface 1230 may provide a communication function between the electronic system 1000 and an external host. Upon receiving a control command from an external host via the host interface 1230, the processor 1210 may control the non-volatile memory device 1100 in response to the control command.

Referring to FIGS. 35 and 36, an electronic system according to an example embodiment may include a main substrate 2001, a main controller 2002 mounted on the main substrate 2001, at least one semiconductor package 2003, and at least one DRAM 2004. The semiconductor package 2003 and the DRAM 2004 may be connected to the main controller 2002 via wiring patterns 2005 formed on the main substrate 2001.

The main substrate 2001 may include a connector 2006 including a plurality of pins coupled to an external host. The number and an arrangement of the plurality of pins in the connector 2006 may vary based on a communication interface between the electronic system 2000 and the external host. In some example embodiments, the electronic system 2000 may communicate with the external host using one of interfaces such as USB (Universal Serial Bus), PCI-Express (Peripheral Component Interconnect Express), SATA (Serial Advanced Technology Attachment), M-Phy for UFS (Universal Flash Storage), etc. In some example embodiments, the electronic system 2000 may operate using power supplied from the external host via the connector 2006. The electronic system 2000 may further include a power management integrated circuit (PMIC) for distributing power supplied from the external host to the main controller 2002 and the semiconductor package 2003.

The main controller 2002 may write data to the semiconductor package 2003 or read data from the semiconductor package 2003, and may improve an operating speed of the electronic system 2000.

The DRAM 2004 may act as a buffer memory for reducing a difference between operation speeds of the semiconductor package 2003 as a data storage space and the external host. The DRAM 2004 included in electronic system 2000 may operate as a cache memory, and may provide a space for temporarily storing data therein in a control operation of the semiconductor package 2003. When the DRAM 2004 is included in the electronic system 2000, the main controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be embodied as a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a bottom surface of each of the semiconductor chips 2200, a connection structure 2400 electrically connecting the semiconductor chips 2200 and the package substrate 2100 to each other, and a molding layer 2500 disposed the package substrate 2100 and covering the semiconductor chips 2200 and the connection structure 2400.

The package substrate 2100 may be embodied as a printed circuit board including package upper pads 2130. Each semiconductor chip 2200 may include an input/output pad 2210. The input/output pad 2210 may correspond to the input/output pad 1101 in FIG. 34.

In some example embodiments, the connection structure 2400 may be embodied as a bonding wire that electrically connects the input/output pad 2210 and the package upper pads 2130 to each other. Accordingly, in each of the first semiconductor package 2003a and the second semiconductor package 2003b, the semiconductor chips 2200 may be electrically connected to each other in a bonding wire scheme, and may be electrically connected to the package upper pads 2130 of the package substrate 2100. In some example embodiments, in each of the first semiconductor package 2003a and the second semiconductor package 2003b, the semiconductor chips 2200 may be electrically connected to each other via a connection structure including a through electrode (Through Silicon Via: TSV) instead of the connection structure 2400 using the bonding wire scheme.

In some example embodiments, the main controller 2002 and the semiconductor chips 2200 may be included in one package. In some example embodiments, the main controller 2002 and the semiconductor chips 2200 may be mounted on a separate interposer substrate different from the main substrate 2001, and the main controller 2002 and the semiconductor chips 2200 may be connected to each other via a wiring formed in the interposer substrate.

In some example embodiments, the package substrate 2100 may be embodied as a printed circuit board. The package substrate 2100 may include a package substrate body 2120, the package upper pads 2130 disposed on a top surface of the package substrate body 2120, package lower pads 2125 disposed on a bottom surface of the package substrate body 2120, or exposed through the bottom surface thereof, and internal lines 2135 disposed in the package substrate body 2120 so as to electrically connect the upper pads 2130 and the lower pads 2125 to each other. The upper pads 2130 may be electrically connected to the connection structures 2400. The lower pads 2125 may be connected to the wiring patterns 2005 of the main substrate 2001 of the electronic system 2000 via conductive connectors 2800 as shown in FIG. 35.

Referring to FIG. 35 and FIG. 36, in the electronic system according to an example embodiment, each of the semiconductor chips 2200 may include the non-volatile memory device as described above using FIG. 1 to FIG. 7. For example, each of the semiconductor chips 2200 may include the peripheral circuit structure PERI and the cell structure CELL stacked on the peripheral circuit structure PERI. In one example, the peripheral circuit structure PERI may include the peripheral circuit substrate 200 and the second wiring patterns 241 and 242 as described above using FIG. 1 to FIG. 7. Further, in one example, the cell structure CELL may include the cell substrate 100, the mold structure MS, the channel structure CH, the block isolation area WLC, and the bit-line BL as described above using FIG. 3 to FIG. 7.

Any functional blocks shown in the figures and described above may be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In concluding the detailed description, those skilled in the art will appreciate that many variations and modifications may be made to the disclosed example embodiments without substantially departing from the principles of the present disclosure. Therefore, the disclosed example embodiments of the disclosure are used in a generic and descriptive sense only and not for purposes of limitation.

1. A non-volatile memory device comprising:
a substrate including a first area and a second area;
a mold structure on the substrate, the mold structure including a plurality of gate electrodes and a plurality of mold insulating films that are alternately stacked on top of each other and stacked in a stepwise manner;
an interlayer insulating film covering the mold structure;
a channel structure on the first area of the substrate, the channel structure extending through the mold structure and connected to the plurality of gate electrodes; and
a through-contact on the second area of the substrate and extending through the interlayer insulating film, wherein
the through-contact includes a first portion in a first trench and a second portion in a second trench, the second trench being on the first trench,
the first portion includes,
a liner film along a sidewall and a bottom surface of the first trench, and
a filling film on the liner film,
the filling film is a multi-grain conductive material, and
the second portion is a single grain conductive material.

2. The non-volatile memory device of claim 1, wherein the first trench and the second trench are positionally offset relative to each other.

3. The non-volatile memory device of claim 1, wherein
a width of the first trench gradually increases and then decreases as the first trench extends away from the substrate, and
a width of the second trench gradually increases and then decreases as the second trench extends away from the substrate.

4. The non-volatile memory device of claim 1, wherein
the filling film includes a first portion on one sidewall of the first trench and a second portion on an opposite sidewall of the first trench, and
a boundary line is at a boundary between the first area and the second area.

5. The non-volatile memory device of claim 1, wherein
the liner film includes a first sub-liner film, and a second sub-liner film on the first sub-liner film,
the first sub-liner film includes at least one of TiN, WN, WCN, or TSN, and
the second sub-liner film includes boron (B).

6. The non-volatile memory device of claim 1, wherein the second portion is a single film.

7. The non-volatile memory device of claim 1, wherein the channel structure includes a first channel and a second channel on the first channel.

8. The non-volatile memory device of claim 7, wherein
the first channel overlaps the first trench in a direction parallel to a top surface of the substrate, and
the second channel overlaps the second trench in the direction parallel to the top surface of the substrate.

9. The non-volatile memory device of claim 1, wherein the through-contact includes a tip portion at a boundary between the first portion and the second portion, and the tip portion is convex toward the substrate.

10. A non-volatile memory device comprising:
a substrate including a first area and a second area;
a mold structure on the substrate, the mold structure including a plurality of gate electrodes and a plurality of mold insulating films that are alternately stacked on top of each other and stacked in a stepwise manner;
an interlayer insulating film covering the mold structure;
a channel structure on the first area of the substrate, the channel structure extending through the mold structure and connected to the plurality of gate electrodes; and
a through-contact on the second area of the substrate and extending through the interlayer insulating film, wherein
the through-contact includes,
a first portion in a first trench and being multiple layers; and
a second portion in a second trench and being a single layer, the second trench is on the first trench,
the first portion includes,
a liner film along a sidewall and a bottom surface of the first trench, and
a filling film on the liner film,
the filling film includes a first portion on one sidewall of the first trench, and a second portion on an opposite sidewall of the first trench, and
a boundary line is at a boundary between the first area and the second area.

11. The non-volatile memory device of claim 10, wherein
the filling film is a multi-grain conductive material,
wherein the second portion is a single grain conductive material.

12. The non-volatile memory device of claim 10, wherein the first trench and the second trench are positionally offset relative to each other.

13. The non-volatile memory device of claim 10, wherein
a width of the first trench gradually increases and then decreases as the first trench extends away from the substrate, and
a width of the second trench gradually increases and then decreases as the second trench extends away from the substrate.

14. The non-volatile memory device of claim 10, wherein
the liner film includes a first sub-liner film and a second sub-liner film on the first sub-liner film,
the first sub-liner film includes at least one of TiN, WN, WCN, or TSN, and
the second sub-liner film includes boron (B).

15. The non-volatile memory device of claim 10, wherein the channel structure includes a first channel and a second channel on the first channel.

16. The non-volatile memory device of claim 15, wherein
the first channel overlaps the first trench in a direction parallel to a top surface of the substrate, and
the second channel overlaps the second trench in the direction parallel to the top surface of the substrate.

17. A method for manufacturing a non-volatile memory device, the method comprising:
providing a substrate including a first area and a second area;
forming a mold structure on the substrate, the mold structure including a plurality of gate electrodes and a plurality of mold insulating films that are stacked in a stepwise manner and are alternately stacked on top of each other;
forming an interlayer insulating film to cover the mold structure;
forming a channel structure on the first area of the substrate to extend through the mold structure and to be connected to the plurality of gate electrodes;
forming a trench on the second area of the substate to extend through the interlayer insulating film, the trench including a first trench and a second trench disposed on the first trench;
forming a pre-liner film along a sidewall and a bottom surface of the trench;
forming an inhibiting layer on a portion of the pre-liner film, which is disposed on a sidewall of the second trench, such that the inhibiting layer is not formed on a portion of the pre-liner film disposed on a sidewall of the first trench; and
forming a through-contact in the trench,
wherein the through-contact includes a first portion disposed in the first trench and a second portion disposed in the second trench,
wherein the first portion includes,
a liner film disposed along the sidewall and a bottom surface of the first trench; and
a filling film disposed on the liner film,
wherein the filling film is made of a multi-grain conductive material,
wherein the second portion is made of a single grain conductive material.

18. The method of claim 17, further comprising:
forming the filling film in the first trench; and
removing the inhibiting layer after forming the filling film.

19. The method of claim 17, wherein the second portion is formed in a bottom-up manner.

20. The method of claim 18, wherein
the pre-liner film includes a pre-first sub-liner film, and a pre-second sub-liner film disposed on the pre-first sub-liner film,
the pre-first sub-liner film includes at least one of TiN, WN, WCN, or TSN, and
the pre-second sub-liner film includes boron (B).

21. (canceled)
